(19) United States
(12) Patent Application Publication
(10) Pub. No.: US 2024/0222018 A1
(43) Pub. Date: Jul. 4, 2024

(54) SUBSTRATE PACKAGE-INTEGRATED OXIDE CAPACITORS AND RELATED METHODS

(71) Applicant: Intel Corporation, Santa Clara, CA (US)

(72) Inventors: Thomas Sounart, Chandler, AZ (US); Henning Braunisch, Phoenix, AZ (US); Aleksandar Aleksov, Chandler, AZ (US); Kristof Darmawikarta, Chandler, AZ (US); Numair Ahmed, Chandler, AZ (US); Darko Grujicic, Chandler, AZ (US); Suddhasattwa Nad, Chandler, AZ (US); Benjamin Duong, Phoenix, AZ (US); Marcel Wall, Phoenix, AZ (US); Shayan Kaviani, Phoenix, AZ (US)

(21) Appl. No.: 18/147,503

(22) Filed: Dec. 28, 2022

(51) Int. Cl. H01G 4/01; H01G 4/30; H01G 4/33; H01L 21/48; H01L 23/538

(52) U.S. Cl. CPC H01G 4/01; H01G 4/306; H01G 4/33; H01L 21/4846; H01L 23/5386; H01L 28/87; H01L 28/92; H01G 4/008

(57) ABSTRACT

Substrate package-integrated oxide capacitors and related methods are disclosed herein. An example apparatus including a first layer and a thin film capacitor including a second layer on the first layer, the second layer defining a plurality of openings and a third layer disposed on the first layer and in the plurality of openings, the second layer and the third layer corresponding to electrodes of a capacitor and a fourth layer disposed between the first layer and the second layer, the third layer including an oxidized material, the third layer forming a dielectric of the capacitor.

### FIELD OF THE DISCLOSURE

This disclosure relates generally to integrated circuit packages and, more particularly, to substrate package-integrated oxide capacitors and related methods.

### BACKGROUND

Integrated circuit (IC) chips and/or semiconductor dies are routinely connected to larger circuit boards such as motherboards and other types of printed circuit boards (PCBs) via a package substrate. Integrated circuit (IC) chips and/or dice (e.g., dies, etc.) have exhibited reductions in size and increases in interconnect densities as technology has advanced.

### BRIEF DESCRIPTION OF THE DRAWINGS

FIG. 1 illustrates an example integrated circuit (IC) package on a printed circuit board.

FIG. 2 is a cross-sectional view of an example package substrate capacitor implemented in accordance with the teachings of this disclosure.

FIGS. 3-7 are cross-sectional views depicting the capacitor of FIG. 2 in various stages of manufacturing.

FIG. 8 is a block diagram of an example manufacturing process for manufacturing the capacitor of FIGS. 2.

FIG. 9-14 are cross-sectional views depicting another capacitor in various stages of manufacturing.

FIG. 15 is a block diagram of an example manufacturing process for manufacturing the capacitor of FIGS. 9-14.

FIGS. 16A-16C are example opening patterns that can be used in conjunction with the capacitor of FIG. 2 or the capacitor of FIG. 14.

FIG. 17-21 are cross-sectional views depicting another capacitor in various stages of manufacturing.

FIG. 22 is a block diagram of an example manufacturing process for manufacturing the capacitor of FIGS. 17-21.

FIG. 23 is a top view of a wafer and dies that may be included in an IC package constructed in accordance with teachings disclosed herein.

FIG. 24 is a cross-sectional side view of an IC device that may be included in an IC package constructed in accordance with teachings disclosed herein.

FIG. 25 is a cross-sectional side view of an IC device assembly that may include an IC package constructed in accordance with teachings disclosed herein.

FIG. 26 is a block diagram of an example electrical device that may include an IC package constructed in accordance with teachings disclosed herein.

In general, the same reference numbers will be used throughout the drawing(s) and accompanying written description to refer to the same or like parts. The figures are not necessarily to scale. Instead, the thickness of the layers or regions may be enlarged in the drawings. Although the figures show layers and regions with clean lines and boundaries, some or all of these lines and/or boundaries may be idealized. In reality, the boundaries and/or lines may be unobservable, blended, and/or irregular.

As used herein, unless otherwise stated, the term “above” describes the relationship of two parts relative to Earth. A first part is above a second part, if the second part has at least one part between Earth and the first part. Likewise, as used herein, a first part is “below” a second part when the first part is closer to the Earth than the second part. As noted above, a first part can be above or below a second part with one or more of: other parts therebetween, without other parts therebetween, with the first and second parts touching, or without the first and second parts being in direct contact with one another.

Notwithstanding the foregoing, in the case of a semiconductor device, “above” is not with reference to Earth, but instead is with reference to a bulk region of a base semiconductor substrate (e.g., a semiconductor wafer) on which components of an integrated circuit are formed. Specifically, as used herein, a first component of an integrated circuit is “above” a second component when the first component is farther away from the bulk region of the semiconductor substrate than the second component.

As used in this patent, stating that any part (e.g., a layer, film, area, region, or plate) is in any way on (e.g., positioned on, located on, disposed on, or formed on, etc.) another part, indicates that the referenced part is either in contact with the other part, or that the referenced part is above the other part with one or more intermediate part(s) located therebetween.

As used herein, connection references (e.g., attached, coupled, connected, and joined) may include intermediate members between the elements referenced by the connection reference and/or relative movement between those elements unless otherwise indicated. As such, connection references do not necessarily infer that two elements are directly connected and/or in fixed relation to each other. As used herein, stating that any part is in “contact” with another part is defined to mean that there is no intermediate part between the two parts.

Unless specifically stated otherwise, descriptors such as “first,” “second,” “third,” etc., are used herein without imputing or otherwise indicating any meaning of priority, physical order, arrangement in a list, and/or ordering in any way, but are merely used as labels and/or arbitrary names to distinguish elements for ease of understanding the disclosed examples. In some examples, the descriptor “first” may be used to refer to an element in the detailed description, while the same element may be referred to in a claim with a different descriptor such as “second” or “third.” In such instances, it should be understood that such descriptors are used merely for identifying those elements distinctly that might, for example, otherwise share a same name.

As used herein, “approximately” and “about” modify their subjects/values to recognize the potential presence of variations that occur in real world applications. For example, “approximately” and “about” may modify dimensions that may not be exact due to manufacturing tolerances and/or other real world imperfections as will be understood by persons of ordinary skill in the art. For example, “approximately” and “about” may indicate such dimensions may be within a tolerance range of +/−10% unless otherwise specified in the below description.

As used herein, the phrase “in communication,” including variations thereof, encompasses direct communication and/or indirect communication through one or more intermediary components, and does not require direct physical (e.g., wired) communication and/or constant communication, but rather additionally includes selective communication at periodic intervals, scheduled intervals, aperiodic intervals, and/or one-time events.

As used herein, “processor circuitry” is defined to include (i) one or more special purpose electrical circuits structured to perform specific operation(s) and including one or more semiconductor-based logic devices (e.g., electrical hardware implemented by one or more transistors), and/or (ii) one or more general purpose semiconductor-based electrical circuits programmable with instructions to perform specific operations and including one or more semiconductor-based logic devices (e.g., electrical hardware implemented by one or more transistors). Examples of processor circuitry include programmable microprocessors, Field Programmable Gate Arrays (FPGAs) that may instantiate instructions, Central Processor Units (CPUs), Graphics Processor Units (GPUs), Digital Signal Processors (DSPs), XPUs, or microcontrollers and integrated circuits such as Application Specific Integrated Circuits (ASICs). For example, an XPU may be implemented by a heterogeneous computing system including multiple types of processor circuitry (e.g., one or more FPGAs, one or more CPUs, one or more GPUs, one or more DSPs, one or more ASICs, etc., and/or a combination thereof) and application programming interface(s) (API(s)) that may assign computing task(s) to whichever one(s) of the multiple types of processor circuitry is/are best suited to execute the computing task(s).

### DETAILED DESCRIPTION

In recent years, the demand for high capacitance density on substrate packages has increased to support the power delivery needs of current generation integrated circuit (IC) packages. Some prior capacitor form factors, including metal-insulator-metal (MIM) capacitors on die, do not provide sufficient capacitance density for some applications, particularly, for higher input voltage power delivery architectures. Other prior capacitor form factors, including multi-layer ceramic capacitors (MLCC), have prohibitive vertical sizes and high inductances that limit processor operating frequency. As such, current capacitor form factors have difficulty scaling to meet growing capacitance density needs.

Examples disclosed herein include package substrate capacitors with thin film capacitors (TFC) having comparatively high surface areas that include insulator layers comprising oxidized materials. Some examples disclosed herein include aluminum-oxide insulator layers formed by the anodic oxidation of a deposited aluminum layer. In some examples disclosed herein, the deposited aluminum layer forms an electrode of the TFC, the aluminum-oxide formed thereon forms an insulator of the TFC, and a copper layer deposited thereon forms another electrode of the TFC. Some examples disclosed herein include openings formed in one of the electrode layers that increases the relative surface area of the corresponding TFC. In some examples disclosed herein, the openings are formed during the anodic oxidation of an adjacent layer by exposing the layer to an acidic bath. Examples disclosed herein increase the available surface area of substrate package capacitors, which increases the available capacitance density of the TFC.

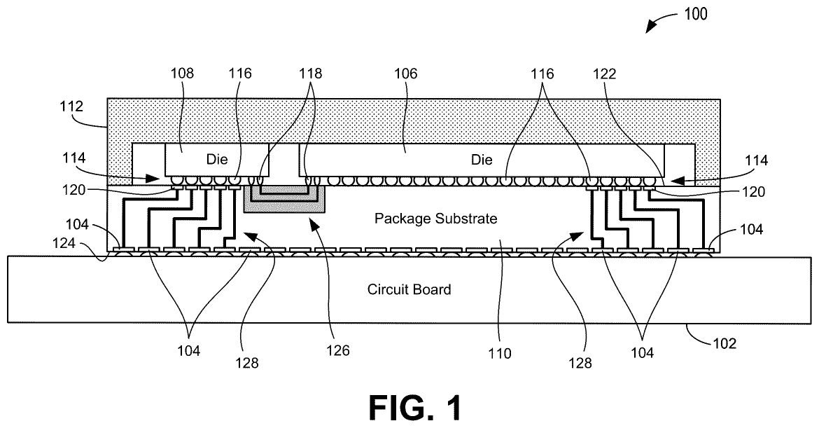

FIG. 1 illustrates an example IC package (e.g., a semiconductor package) 100 constructed in accordance with the teachings disclosed herein. In the illustrated example, the IC package 100 is electrically coupled to a circuit board 102 via an array of contact pads or lands 104 on a mounting surface (e.g., a bottom surface) of the package. In some examples, the IC package 100 may include balls, pins, and/or pads, in addition to or instead of the contact pads 104, to enable the electrical coupling of the IC package 100 to the circuit board 102. In this example, the IC package 100 includes two semiconductor (e.g., silicon) dies 106, 108 (sometimes also referred to as chips or chiplets) that are mounted to a package substrate 110 and enclosed by a package lid or mold compound 112. While the example IC package 100 of FIG. 1 includes two dies 106, 108, in other examples, the IC package 100 may have only one die or more than two dies. In some examples, one of the dies 106, 108 (or a separate die) is embedded in the package substrate 110. The dies 106, 108 can provide any suitable type of functionality (e.g., data processing, memory storage, etc.).

In the illustrated example, each of the dies 106, 108 is electrically and mechanically coupled to the substrate 110 via corresponding arrays of interconnects 114. In FIG. 1, the interconnects are shown as bumps. However, the interconnects 114 may be any other type of electrical connection in addition to or instead of the bumps shown (e.g., balls, pins, pads, wire bonding, etc.). The electrical connections between the dies 106, 108 and the substrate 110 (e.g., the interconnects 114) are sometimes referred to as first level interconnects. By contrast, the electrical connections between the IC package 100 and the circuit board 102 (e.g., the pads 104) are sometimes referred to as second level interconnects. In some examples, one or both of the dies 106, 108 may be stacked on top of one or more other dies and/or an interposer. In such examples, the dies 106, 108 are coupled to the underlying die and/or interposer through a first set of first level interconnects and the underlying die and/or interposer may be connected to the package substrate 110 via a separate set of first level interconnects associated with the underlying die and/or interposer. Thus, as used herein, first level interconnects refer to interconnects (e.g., balls, bumps, pins, pads, wire bonding, etc.) between a die and a package substrate or a die and an underlying die and/or interposer.

As shown in FIG. 1, the interconnects 114 of the first level interconnects include two different types of bumps, namely, core bumps 116 and bridge bumps 118. As used herein, core bumps are bumps on dies through which electrical signals pass between the dies and other components either within an IC package containing the dies (e.g., a different die) or external to the IC package. Thus, as shown in the illustrated example, when the dies 106, 108 are mounted to the package substrate 110, the core bumps 116 are physically connected and electrically coupled to contact pads 120 on an inner surface 122 of the substrate 110. The contact pads 120 on the inner surface 122 of the package substrate 110 are electrically coupled to the landing pads 104 on the bottom (external) surface 124 of the substrate 110 (e.g., a surface opposite the inner surface 122) via internal interconnects 126 within the substrate 110. As a result, there is a complete signal path between the bumps 116 of the dies 106, 108 and the landing pads 104 mounted to the circuit board 102 that pass through the contact pads 120 and the interconnects 126 provided therebetween.

As used herein, bridge bumps are bumps on the dies through which electrical signals pass between different ones of the dies within an IC package. More particularly, bridge bumps differ from core bumps in that bridge bumps electrically connect two or more different dies via an interconnect bridge embedded (e.g., the interconnect bridge 128 of FIG. 1) embedded in an underlying substrate (e.g., the package substrate 110). As represented in FIG. 1, core bumps 116 are typically larger than bridge bumps 118. In some examples, the interconnect bridge 128 and the associated bridge bumps 118 are omitted.

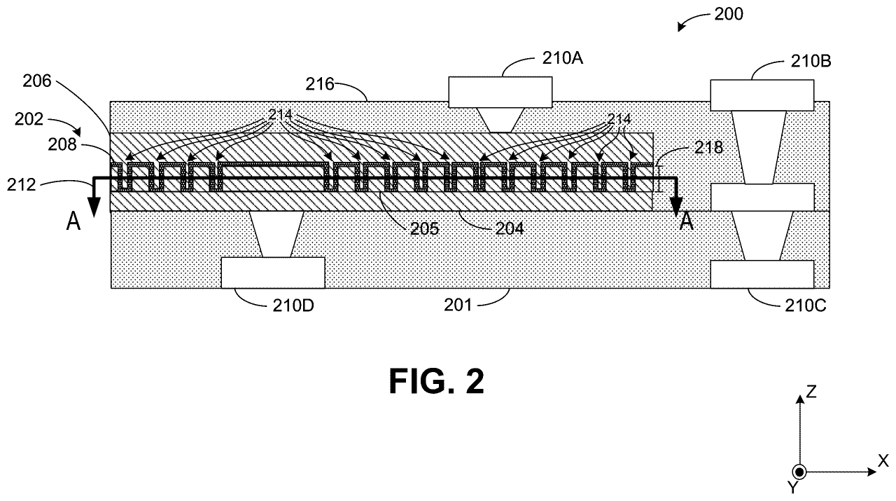

FIG. 2 is a cross-sectional view of an example capacitor structure 200 deposited on an example first substrate layer 201 implemented in accordance with the teachings of this disclosure. In the illustrated example of FIG. 2, the capacitor structure 200 includes an example thin film capacitor (TFC) 202 including an example first bottom electrode layer 204, an example second bottom electrode layer 205, an example top electrode layer 206, and an example dielectric layer 208. The capacitor structure 200 includes an example first via 210A, an example second via 210B, an example third via 210C, and an example fourth via 210D. In the illustrated example of FIG. 2, the capacitor structure 200 is cut by an example cross-sectional line 212 along the overlap of the second bottom electrode layer 205, the top electrode layer 206, and the dielectric layer 208.

In the illustrated example of FIG. 2, the thin film capacitor 202 is deposited between the first substrate layer 201 and an example second substrate layer 216. In the illustrated example of FIG. 2, the substrate layers 201, 216 can be composed of any suitable non-conductive material. In some examples, the first substrate layer 201 can be a core of the package substrate (e.g., the package substrate 110 of FIG. 1, etc.). In some such examples, the substrate core can be composed of glass. Additionally or alternatively, the first substrate layer 201 can be a build-up layer of the package substrate disposed above (e.g., outboard of, etc.) of the substrate core, etc.). In some such examples, the capacitor structure 200 can be formed in one or both of the substrate layers 201, 216 during the fabrication of the package substrate (e.g., in situ, etc.).

The thin film capacitor 202 is a plate capacitor composed of the bottom electrode layers 204, 205, the top electrode layer 206, and the dielectric layer 208. The top electrode layer 206 of the thin film capacitor 202 can be composed of any suitable electrically conductive material(s), including copper, aluminum, nickel, gold, and silver, etc. In some examples, the top electrode layer 206 can be composed of multiple material(s). For example, a first material (e.g., titanium nitride (TiN), Ruthenium, etc.) can be deposited (e.g., via ALD, via CVD, etc.) in the openings 214 and a second material (e.g., copper, etc.) can be deposited thereon. In the illustrated example of FIG. 2, the bottom electrode layers 204, 205 are composed of a same suitable electrically conductive material, including copper, aluminum, nickel, gold, and silver, etc. In other examples, the bottom electrode layers 204, 205 can be composed of different materials. For example, one or both of the bottom electrode layers 204, 205 can be composed of a material that is suitable for anodic oxidation and electrically conductive (e.g., aluminum, tantalum, etc.). In some such examples, the dielectric layer 208 can be formed via the oxidation of the first bottom electrode layer 204 and/or the second bottom electrode layer 205.

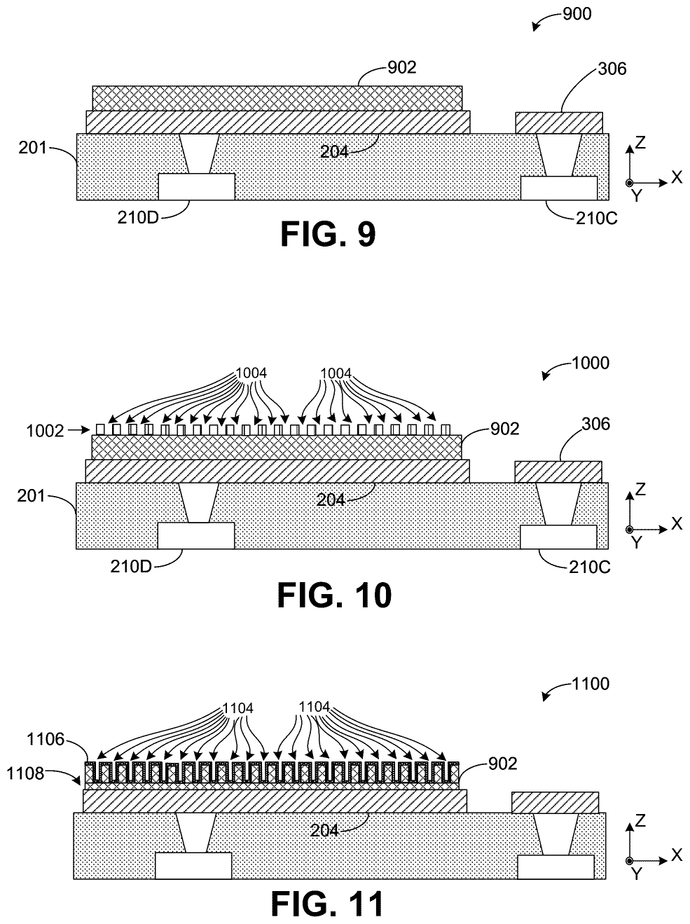

The dielectric layer 208 is a thin film layer separating the bottom electrode layers 204, 205 from the top electrode layer 206. In the illustrated example of FIG. 2, the dielectric layer 208 is composed of aluminum oxide (e.g., AlO₃, etc.) that is formed by the anodic oxidation of a thin film (not illustrated in FIG. 2) disposed on the second bottom electrode layer 205 (e.g., exposing the thin film to an electric field in an anodic oxidation bath, etc.). Aluminum oxide is a high-k dielectric material, increasing the efficiency of the dielectric layer 208. In other examples, the dielectric layer 208 can be composed of any other suitable oxide, depending on the material of the deposited film (e.g., tantalum oxide if the film is composed of tantalum, titanium oxide if the film is composed of titanium, etc.). In the illustrated example of FIG. 2, the dielectric layer 208 is conformally deposited on the bottom electrode layer 204. As such, the dielectric layer 208 extends into example openings 214 in the bottom electrode layer 204. In other examples, the second bottom electrode layer 205 can be composed of a material that forms a dielectric oxide when anodically oxidized (e.g., aluminum, etc.). An example of a dielectric layer similar to the dielectric layer 208 partially formed from the bottom electrode is described below in conjunction with FIGS. 9-15 and FIGS. 17-22.

The capacitor structure 200 provides capacitance to support power delivery to dies coupled to the package substrate (e.g., the dies 106, 108 of FIG. 1, etc.). In the illustrated example of FIG. 2, the plurality of the example openings 214 in the second bottom electrode layer 205 increase the capacitance density of the capacitor structure when compared to prior capacitors that include layers that are disposed entirely within a single plane (e.g., a planar top electrode, a planar bottom electrode, a planar dielectric layer, etc.). The openings 214 increase the surface area (e.g., the contact area, etc.) between the top electrode layer 206 and the bottom electrode layers 204, 205 without increasing the relative footprint of the thin film capacitor 202 (e.g., the size of the TFC in the x-y plane, etc.) or the height of the thin film capacitor 202.

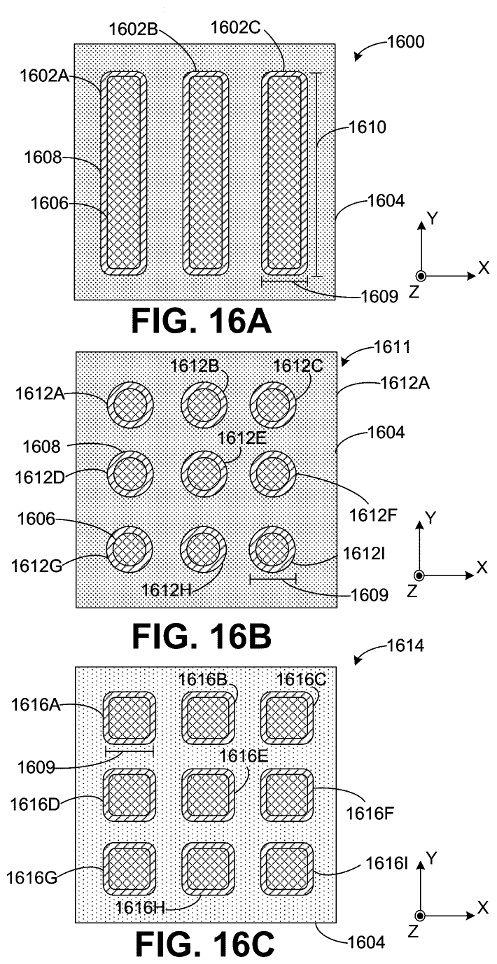

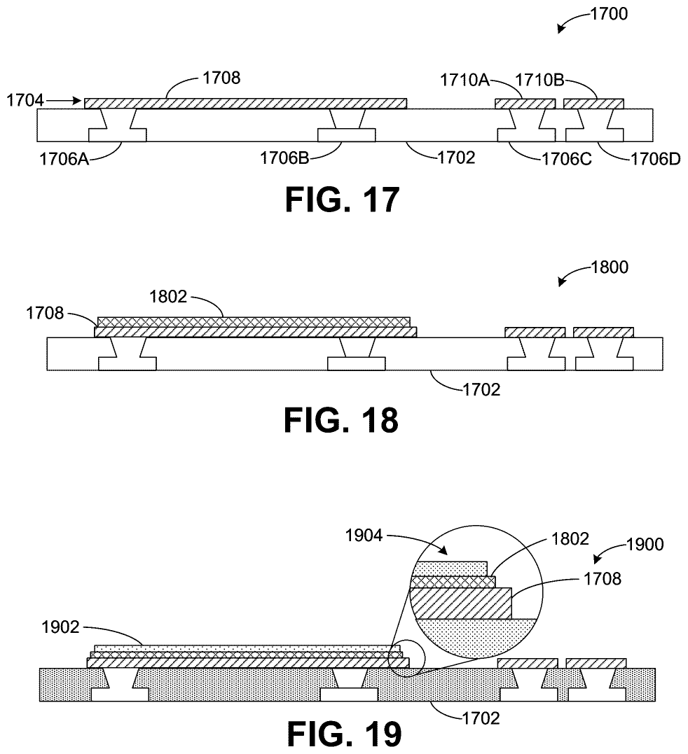

In some examples, the openings 214 can be formed in the second bottom electrode layer 205 via negative manufacturing (e.g., patterning/etching, etc., etc.) or additive manufacturing (e.g., by depositing the second bottom electrode layer 205 with the openings, etc.). In some such examples, the openings 214 can be formed in an ordered (e.g., structured, regular, organized, etc.) pattern in the capacitor structure 200. In the illustrated example of FIG. 2, the openings 214 and the second bottom electrode layer 205 have an example depth 218. Example ordered configurations of the openings 214 are described below in conjunction with FIGS. 16A-16C. In other examples, the openings 214 can be formed during the formation of the dielectric layer 208. In some such examples, the material used to form the dielectric layer 208 (e.g., aluminum, tantalum, titanium, etc.) can be formed during pore formation in an anodic oxidation process in an acidic bath (e.g., a pH of less than 5, etc.). In such examples, the openings 214 are irregular pores (e.g., an unstructured porous network, an irregular porous network, a random porous network, etc.) in the capacitor structure 200. The formation of a capacitor structure similar to the capacitor structure 200 including an irregular pore structure is described below in conjunction with FIGS. 17-22.

The vias 210A, 210B, 210C, 210D transmit electrical signals between layers of the capacitor structure 200. In the illustrated example of FIG. 2, the first via 210A is electrically coupled to the top electrode layer 206 and the fourth via 210D is electrically coupled to the bottom electrode layers 204, 205. As such, electrical signals can be transmitted between the bottom of the capacitor structure 200 subsequentially through the fourth via 210D, the thin film capacitor 202, and the first via 210A. The second via 210B and the third via 210C permit electrical signals to pass through the capacitor structure 200 without passing through the thin film capacitor 202. In some examples, the second via 210B and the third via 210C can be absent. In some examples, the vias 210A, 210B, 210C, 210D can be filled with a conductive material such as a metal. In some examples, the capacitor structure 200 can include additional connections, traces, and/or vias (not illustrated).

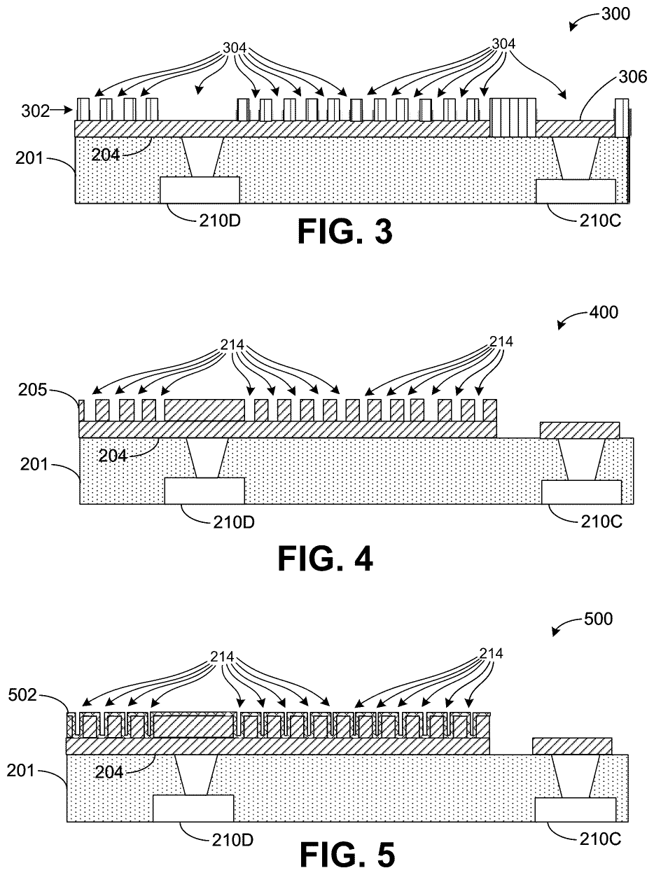

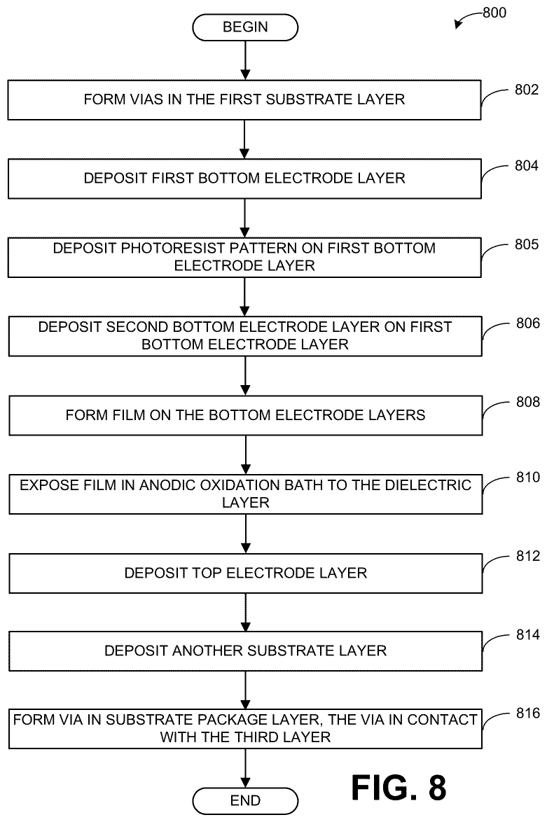

FIGS. 3-7 depict a plurality of intermediate stages in an example process to manufacture the capacitor structure 200 of FIG. 2. In other examples, the capacitor structure similar to the capacitor structure 200 of FIG. 2 can be manufactured via a process that includes intermediate stages different than the ones illustrated in conjunction with FIGS. 3-7. Example operations to manufacture the capacitor structure 200 are described below in conjunction with FIG. 8.

FIG. 3 is a cross-sectional view of an example first intermediate stage 300 of the fabrication of the capacitor structure 200. In the illustrated example of FIG. 3, the first bottom electrode layer 204 has been deposited on the first substrate layer 201 and an example photoresist pattern 302 including example openings 304 has been deposited. The first bottom electrode layer 204 is deposited on and abuts the first substrate layer 201. For example, the first bottom electrode layer 204 can be deposited via atomic layer deposition (ALD) and/or chemical vapor deposition (CVD), etc. Additionally or alternatively, the first bottom electrode layer 204 can be deposited via electroplating. In some such examples, a seed layer can be deposited (e.g., via ALD, via CVD, etc.) on the first substrate layer 201 to facilitate the electroplating of the first bottom electrode layer 204. The first bottom electrode layer 204 can be composed of copper and/or another suitable conductive material.

The photoresist pattern 302 is deposited on the first bottom electrode layer 204. For example, the photoresist pattern 302 can be deposited via lithography. In some examples, the photoresist pattern 302 occupies the physical space of the openings 214 of FIG. 2 and the openings 304 occupy the physical space of the second bottom electrode layer 205 of FIG. 2. In some examples, the photoresist pattern 302 can be composed of a photo-sensitive material that becomes soluble when exposed to a particular wavelength of light. In other examples, the photoresist pattern 302 and the openings 304 can be formed by any other suitable means. In some examples, prior to the deposition of the photoresist pattern 302 on the first bottom electrode layer 204, a seed layer (not illustrated) can be deposited on the first bottom electrode layer 204.

FIG. 4 is a cross-sectional view of an example second intermediate stage 400 of the fabrication of the capacitor structure 200. In the illustrated example of FIG. 4, the second bottom electrode layer 205 is deposited via electroplating (e.g., electrochemical deposition, etc.) on the seed layer deposited on the first bottom electrode layer 204. In some such examples, the photoresist pattern 302 masks the seed layer, which causes the formation of the second bottom electrode layer 205 in the areas not masked by the photoresist pattern 302. In other examples, the bottom electrode layer 205 can be deposited in any other suitable manner (e.g., PVD, CVD, etc.). In some examples, after the bottom electrode layer 205 has been deposited, the photoresist pattern 302 can be removed (e.g., via ultra-violet light and a bath, etc.) and the exposed portions of the seed layer (e.g., the portions that were previously masked by the photoresist pattern, etc.) via etching.

FIG. 5 is a cross-sectional view of an example third intermediate stage 500 of the fabrication of the capacitor structure 200. In the illustrated example of FIG. 5, an example thin film 502 has been deposited on the exposed portions of the bottom electrode layers 204, 205. In the illustrated example of FIG. 5, the thin film 502 is deposited via a conformal deposition process (e.g., ALD, CVD, etc.) such that thin film 502 is deposited on the sides and bottom of the openings 214 associated with the bottom electrode layers 204, 205. In some examples, the depositing of the thin film 502 can be omitted. In such examples, the thin film 502 can be formed via the anodic oxidation of the second bottom layer 205. The thin film 502 can be composed of any suitable material that oxidizes when exposed to an electric field in an anodic oxidation bath (e.g., aluminum, tantalum, etc.).

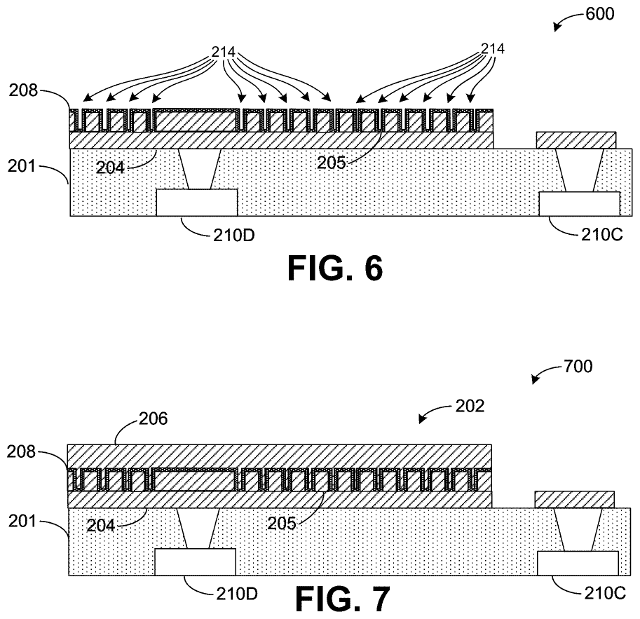

FIG. 6 is a cross-sectional view of an example fourth intermediate stage 600 of the fabrication of the capacitor structure 200. For example, the thin film 502 deposited on the bottom electrode layers 204, 205 is exposed to an aqueous anodic oxidation bath with a neutral pH (e.g., a pH of greater than 5 but less than 7, etc.) and/or an acidic pH (e.g., a pH of less than 5, etc.) to form the dielectric layer 208. In some examples, if the thin film 502 is exposed to an acidic pH, the dielectric layer 208 is a porous network of aluminum oxide. In some examples, if the thin film 502 is exposed to a neutral pH, the thin film 502 forms a dense network of aluminum oxide. Examples dielectric layers including a porous network are described below in conjunction with FIG. 11 and FIGS. 17-22.

FIG. 7 is a cross-sectional view of an example fifth intermediate stage 700 of the fabrication of the capacitor structure 200. In the illustrated example of FIG. 7, the top electrode layer 206 has been deposited on the dielectric layer 208. For example, the top electrode layer 206 can be deposited via electroplating. In some such examples, a seed layer (not illustrated) is deposited on the dielectric layer 208 prior to the plating of the top electrode layer 206, etc. In other examples, the top electrode layer 206 can be deposited via CVD and/or ALD. The top electrode layer 206 can be composed of any suitable conductive material(s) (e.g., copper, aluminum, silver, gold, titanium nitride, etc.). In some such examples, a first material (e.g., titanium nitride, etc.) can be deposited in the openings 214 and a second material (e.g., copper, etc.) can be deposited thereon. In some examples, during the deposition of the top electrode layer 206, other components of the capacitor structure 200 (e.g., the third via 210C, etc.) can be masked via a resist to prevent the material of the top electrode layer 206 from being deposited thereon. In some examples, after the top electrode layer 206 has been deposited, the thin film capacitor 202 has been formed. In some examples, the capacitor structure 200 can be completed by depositing a substrate layer (e.g., the second substrate layer 216 of FIG. 2, etc.) and forming additional vias (e.g., the first via 210A, the second via 210B, etc.) therein. In other examples, the additional structures can be deposited on the top electrode layer 206 prior to the depositing of the second substrate layer 216.

FIG. 8 is a flow diagram of example operations 800 that can be used to manufacture the capacitor 200 of FIGS. 2-7. The example operations 800 begin at block 802, at which the third via 210C and the fourth via 210D are formed within the first substrate layer 201. For example, the vias 210C, 210D can be formed by negative manufacturing processes on (e.g., laser drilling, etc.) the substrate layer to form openings corresponding to the vias 210C, 210D, depositing a resist layer on unremoved portions of the first substrate layer 201, and plating a conductive material (e.g., copper, etc.) within the openings. In other examples, the vias 210C, 210D can be formed by any other suitable manufacturing process. In other examples, some or all of the vias 210C, 210D can be absent.

At block 804, the first bottom electrode layer 204 is deposited on the first substrate layer 201. For example, the first bottom electrode layer 204 can be deposited via electroplating. In some such examples, a seed layer can be deposited on the first substrate layer 201 prior to the deposition of the first substrate layer 201. In some examples, the seed layer can be used as a catalyst to electroplate the first bottom electrode layer 204. In some such examples, the first bottom electrode layer 204 is deposited in a manner that forms the interconnect 306 on the third via 210C. Additionally or alternatively, the first bottom electrode layer 204 can be deposited over the entirety of the first substrate layer 201 and a photoresist mask can be deposited after the first bottom electrode layer 204. In such examples, portions of the first bottom electrode layer 204 can be removed via lithography (e.g., a portions adjacent to the interconnect 306, etc.).

At block 805, the photoresist pattern 302 is deposited on the first bottom electrode layer 204. For example, the photoresist pattern 302 can be deposited via lithography. In some examples, the photoresist pattern 302 includes the openings 304 occupies the physical space of the next layer of the bottom electrode (e.g., the second bottom electrode layer 205, etc.). In some examples, the photoresist pattern 302 can be composed of a photo-sensitive material that becomes soluble when exposed to a particular wavelength of light. In other examples, the photoresist pattern 302 and the openings 304 can be formed by any other suitable means. In some examples, prior to the deposition of the photoresist pattern 302 on the first bottom electrode layer 204, a seed layer can be deposited on the first bottom electrode layer 204. The point of fabrication after completion of block 814 corresponds to the structure of the first intermediate stage 300 of FIG. 3.

At block 806, the second bottom electrode layer 205 is deposited on the first bottom electrode layer 204. For example, the second bottom electrode layer 205 is deposited via electroplating (e.g., electrochemical deposition, etc.) on the seed layer deposited on the first bottom electrode layer 204. In some such examples, the photoresist pattern 302 deposited during the execution of block 805 masks the seed layer, which causes the formation of the second bottom electrode layer 205 in the areas not masked by the photoresist pattern 302. In some such examples, the second bottom electrode layer 205 is formed with the openings 214 (e.g., corresponding to the photoresist pattern 302, etc.). In some examples, after the bottom electrode layer 205 has been deposited, the photoresist pattern 302 can be removed (e.g., via ultra-violet light and a bath, etc.) and the exposed portions of the seed layer (e.g., the portions that were previously masked by the photoresist pattern, etc.) via etching. In other examples, the bottom electrode layer 205 can be deposited in any other suitable manner (e.g., PVD, CVD, etc.) and the openings 214 can be formed via another process (e.g., lithography, etching, etc.). The second bottom electrode layer 205 can be composed of any suitable conductive material (e.g., copper, etc.) and/or any suitable material that forms a dielectric oxide when anodically oxidized (e.g., aluminum, tantalum, etc.). The point of fabrication after completion of block 814 corresponds to the structure of the second intermediate stage 400 of FIG. 4.

At block 808, the thin film 502 is formed on the bottom electrode layers 204, 205. For example, the thin film 502 can be deposited with ALD and/or CVD. In other examples, if the second bottom layer 205 is composed of a suitable material, the thin film 502 can be formed via the oxidation of the second bottom electrode layer 205. In such examples, block 808 and block 810 are executed concurrently. At block 810, the thin film 502 is exposed to an anodic oxidation bath and an applied electric field to form the dielectric layer 208. For example, a neutral pH anodic bath can be applied to the thin film 502 to form the dielectric layer 208 including a non-porous (e.g., dense, etc.) internal structure. In some examples, the aqueous anodic oxidation bath can be composed of water (e.g., distilled H₂O, etc.) with an approximately equal amount of H⁺ ions and OH ions and an electrical current flowing through. The aqueous anodic oxidation strips electrons from the thin film 502, which causes the formation of aluminum oxide per the following half-reaction at the anode:

$$2 A l + 3 {H}_{2} O \to {Al}_{2} {O}_{2} + 6 {H}^{+} + 6 {e}^{-}$$

In other examples, the aqueous solution applied to the thin film 502 can have an acidic pH. In some such examples, the resulting dielectric layer can have a porous internal structure. The point of fabrication after completion of block 808 corresponds to the structure of the fourth intermediate stage 600 of FIG. 6.

At block 812, the top electrode layer 206 is deposited. For example, the top electrode layer 206 can be deposited via electroplating. In some such examples, a seed layer (not illustrated) is deposited on the dielectric layer 208 prior to the plating of the top electrode layer 206. In other examples, the top electrode layer 206 can be deposited via CVD and/or ALD. The top electrode layer 206 can be composed of any suitable conductive material (e.g., copper, aluminum, silver, gold, etc.). In some examples, during the deposition of the top electrode layer 206, other components of the capacitor structure 200 (e.g., the third via 210C, exposed areas of the first substrate layer 201, etc.) can be masked to prevent the material of the top electrode layer 206 from being deposited thereon. The point of fabrication after completion of block 812 corresponds to the structure of the fifth intermediate stage 700 of FIG. 7.

At block 814, another substrate layer is deposited. For example, the second substrate layer 216 can be deposited on the top electrode layer 206 and other components of the capacitor structure (e.g., the third via 210C, exposed portions of the first substrate layer 201, etc.). In some examples, the second substrate layer 216 can be composed of a non-conductive (e.g., epoxy, etc.) and/or organic material. At block 816, the first via 210A and the second via 210B are formed in the second substrate layer 216 and are in contact with the top electrode layer 206. For example, the vias 210A, 210B can be formed by negative manufacturing (e.g., laser drilling, etc.), depositing a resist layer on unremoved portions of the second substrate layer, and plating a conductive material (e.g., copper, etc.) within the openings. In other examples, the additional vias can be formed by any other suitable manufacturing process. The operations 800 end.

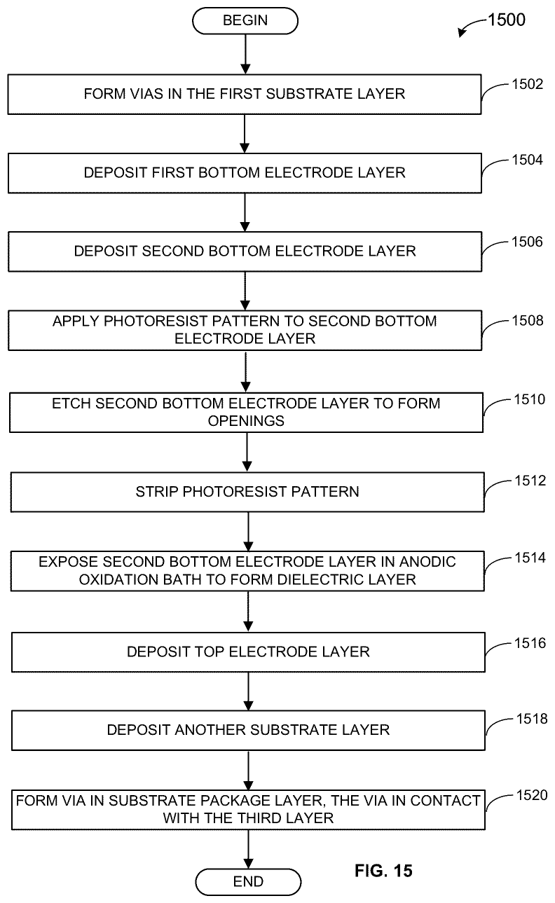

FIGS. 9-14 depict a plurality of intermediate stages in an example process to manufacture another capacitor structure 1400, similar to the capacitor structure 200 of FIG. 2, implemented in accordance. It should be appreciated that other processes can be used to manufacture the capacitor structure of FIGS. 9-14. Example operations to manufacture the capacitor structure of FIGS. 9-14 are described below in conjunction with FIG. 15.

FIG. 9 is a cross-sectional view of an example first intermediate stage 900 of the fabrication of the capacitor structure 1400 of FIG. 14. In the illustrated example of FIG. 9, the first intermediate stage 900 occurs on the first substrate layer 201 of FIG. 2 after the deposition of the first bottom electrode layer 204. In the illustrated example of FIG. 9, the first substrate layer 201 of FIG. 2 includes the vias 210C, 210D of FIG. 9. In other examples, one or both of the vias 210C, 210D are absent. In the illustrated example of FIG. 9, an example second bottom electrode layer 902 is deposited on the first bottom electrode layer 204 (e.g., a carrier layer, etc.). For example, the second bottom electrode layer 902 can be deposited on the first bottom electrode layer 204 via electroplating (e.g., a seed can be deposited on the first bottom electrode layer 204 prior to the depositing of the second bottom electrode layer 902, etc.), CVD, ALD, and/or physical vapor deposition (PVD). In some examples, the first bottom electrode layer 204 can be absent. In such examples, the second bottom electrode layer 902 can be deposited directly on the first substrate layer 201. However, depending on the material of the first substrate layer 201 and/or the material of the second bottom electrode layer 902, electrochemical principles can make depositing the second bottom electrode layer 902 directly on the first substrate layer 201 impractical (e.g., aluminum may not adhere well to glass, etc.)

FIG. 10 is a cross-sectional view of an example second intermediate stage 1000 of the fabrication of the capacitor structure 1400 of FIG. 14. In the illustrated example of FIG. 10, an example photoresist pattern 1002 including example openings 1004 has been deposited on the second bottom electrode layer 902. The photoresist pattern 1002 is deposited on the second bottom electrode layer 902. For example, the photoresist pattern 1002 can be deposited via lithography. In some examples, the photoresist pattern 1002 masks the second bottom electrode layer 902 such that the openings 1004 correspond to the portion of the second bottom electrode layer 902 that will be removed via negative etching. In some examples, the photoresist pattern 1002 can be composed of a photo-sensitive material that becomes soluble when exposed to a particular wavelength of light. In other examples, the photoresist pattern 1002 and the openings 1004 can be formed by any other suitable means.

FIG. 11 is a cross-sectional view of an example third intermediate stage 1100 of the fabrication of the capacitor structure 1400 of FIG. 14. In the illustrated example of FIG. 14, the second bottom electrode layer 902 has been etched (e.g., wet etching, dry etching, etc.) using the example photoresist pattern 1002 to form example openings 1104 in the second bottom electrode layer 902. In the illustrated example of FIG. 11, an example dielectric layer 1106 is formed on the second bottom electrode layer 902. In the illustrated example of FIG. 11, the second bottom electrode layer 902 and the first bottom electrode layer 204 forms an example bottom electrode 1108 of the capacitor structure 1400 of FIG. 14.

In the illustrated example of FIG. 11, the openings 1104 in the second bottom electrode layer 902 do not extend through the entire thickness of the second bottom electrode layer 902 to prevent direct contact (e.g., a short, etc.) between the electrodes of the capacitor structure 1400. For example, the remaining layer of the second bottom electrode layer 902 at the bottom of the openings 1104 is oxidized to form the portion of the dielectric layer 1106 at the bottom of the openings 1104. In some examples, to prevent the openings 1104 from extending through the second bottom electrode layer 902, the etching of the second bottom electrode layer 902 is a timed etch. In other examples, the openings 1104 can be formed in any other suitable manner.

After the formation of the openings 1104, the remaining portion of the second bottom electrode layer 902 is exposed to an electric field in an aqueous anodic oxidation bath with a neutral pH (e.g., a pH of greater than 5 but less than 7, etc.) and/or an acidic pH (e.g., a pH of less than 5, etc.) to form the dielectric layer 208. In some examples, if the second bottom electrode layer 902 is exposed to an acidic pH, the dielectric layer 1106 is a porous network of aluminum oxide. In some examples, if the second bottom electrode layer 902 is exposed to a neutral pH, the thin film 502 forms a dense network of aluminum oxide.

The openings 1104 are a series of gaps (e.g., trenches, holes, etc.) in the second bottom electrode layer 902. In the illustrated example of FIG. 11, the openings 1104 are ordered (e.g., a series of regularly shaped trenches, a series of regularly shaped openings, etc.) that are evenly spaced. In other examples, the openings 1104 can be random and/or semi-random. The openings 1104 increase the relative surface area between the bottom electrode 1108 and a top electrode (e.g., the top electrode 1304 of FIG. 13, etc.) of the capacitor structure 1400 of FIG. 14. Example configurations of the openings 1104 are described below in conjunction with FIGS. 16A-16C.

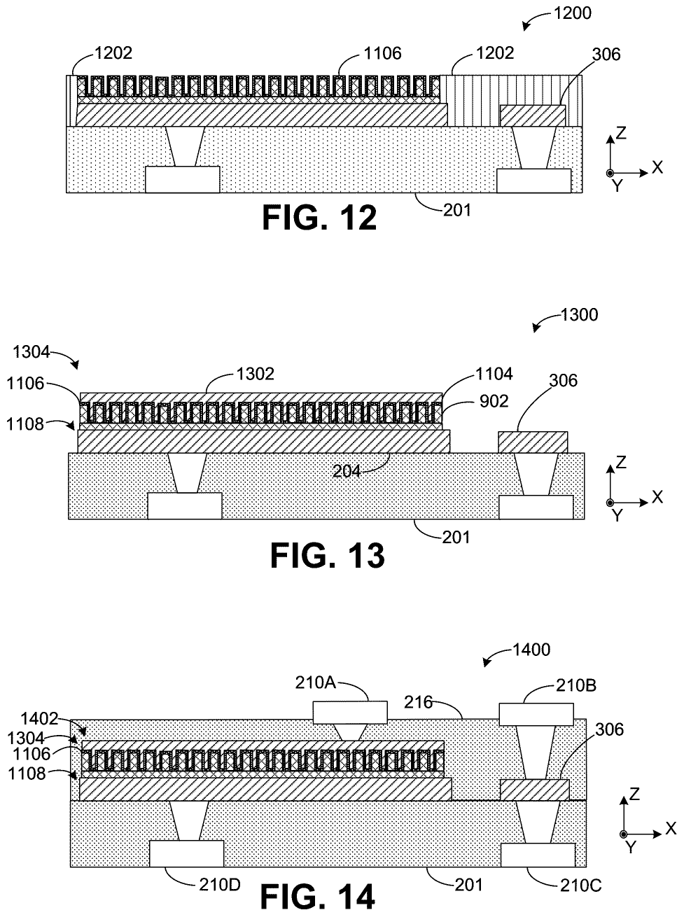

FIG. 12 is a cross-sectional view of an example fourth intermediate stage 1200 of the fabrication of the capacitor structure 1400 of FIG. 14. In the illustrated example of FIG. 12, an example photoresist pattern 1202 has been deposited on the exposed portions of the first substrate layer 201 (e.g., the portions of the first substrate layer 201 not covered by the first bottom electrode layer 204, etc.). The photoresist pattern 1202 is composed of a photo-sensitive material that becomes soluble when exposed to a specific frequency band of light. In some examples, the photoresist pattern 1202 can be deposited via lithography. In other examples, the photoresist pattern 1202 can be deposited in any other suitable manner.

FIG. 13 is a cross-sectional view of an example fifth intermediate stage 1300 of the fabrication of the capacitor structure 1400 of FIG. 14. In the illustrated example of FIG. 13, an example top electrode layer 1302 is deposited on the portions of the capacitor structure 1400 not masked by the photoresist pattern 1202 of FIG. 12. The top electrode layer 1302 forms an example top electrode 1304 of the capacitor structure 1400. In some examples, the top electrode 1304 can be formed by additional layers in addition to the top electrode layer 1302.

In the illustrated example of FIG. 13, the top electrode layer 1302 is deposited in a manner that fills the openings 1104 of FIG. 11 and forms a planar surface on the top of the bottom electrode layer 902. For example, top electrode layer 1302 can be deposited via ALD, CVD, etc. In some such examples, the top electrode layer 1302 can include Titanium Nitride (TiN, Tinite) and/or Ruthenium (Ru). In some such examples, the top electrode layer 1302 can include an additional layer deposited thereon (e.g., a layer of copper disposed thereon via electroplating, etc.). Additionally or alternatively, the top electrode layer 1302 can be composed of a conducting polymer paste. In some examples, if the dielectric layer 1106 is porous, the top electrode layer 1302 can be deposited in a manner that fills the pores of the dielectric layer 1106. In the illustrated example of FIG. 13, after the top electrode layer 1302 has been deposited, photoresist pattern 1202 of FIG. 12 is removed (e.g., via ultra-violet light and a bath, etc.).

FIG. 14 is a cross-sectional view of the example capacitor structure 1400 after the completion of the intermediate stages 900, 1000, 1100, 1200, 1300 of FIGS. 9-14. The example second substrate layer 216 is deposited on the top electrode layer 1302 and the exposed portions of the first substrate layer 201 and the vias 210A, 210B are drilled in the second substrate layer 216 to complete the example capacitor structure 1400. The capacitor structure 1400 includes an example thin film capacitor 1402, which is formed by the bottom electrode 1108, the dielectric layer 1106, and the top electrode 1304.

The thin film capacitor 1402 and the capacitor structure 1400 provide capacitance for the package substrate (e.g., the package substrate 110, etc.) to support power delivery to dies coupled to the package substrate (e.g., the dies 106, 108 of FIG. 1, etc.). In the illustrated example of FIG. 14, the openings 1104 increase the contact area between the top electrode 1304 and the bottom electrode 1108 (e.g., through the dielectric layer 1106, etc.), which increases the capacitance density of the capacitor structure 1400 when compared to prior capacitors that include layers that are disposed entirely within a single plane (e.g., a planar top electrode, a planar bottom electrode, a planar dielectric layer, etc.) without increasing the relative footprint of the thin film capacitor 1402 (e.g., the size of the TFC in the x-y plane, etc.) or the height of the thin film capacitor 1402. In some examples, if the dielectric layer 1106 is porous, the comparative contact area of the thin film capacitor 1402 is further increased, which further increases the capacitance density offered by the thin film capacitor 1402.

FIG. 15 is a flow diagram of example operations 1500 that can be used to manufacture the capacitor structure 1400 of FIG. 14. The example operations 1500 begin at block 1502, at which the third via 210C and the fourth via 210D are formed within the first substrate layer 201. For example, the vias 210C, 210D can be formed by negative manufacturing processes (e.g., laser drilling, etc.) on the substrate layer 201 to form openings corresponding to the vias 210C, 210D, depositing a resist layer on unremoved portions of the first substrate layer 201, and plating a conductive material (e.g., copper, etc.) within the openings. In other examples, the vias 210C, 210D can be formed by any other suitable manufacturing process. In other examples, some or all of the vias 210C, 210D can be absent.

At block 1504, the first bottom electrode layer 204 is deposited on the first substrate layer 201. For example, the first bottom electrode layer 204 can be deposited via electroplating. In some such examples, a seed layer can be deposited on the first substrate layer 201 prior to the deposition of the first substrate layer 201. In some examples, the seed layer can be used as a catalyst to electroplate the first bottom electrode layer 204. In some such examples, the first bottom electrode layer 204 is deposited in a manner that forms the interconnect 306 on the third via 210C. Additionally or alternatively, the first bottom electrode layer 204 can be deposited over the entirety of the first substrate layer 201 and a photoresist mask can be deposited after the first bottom electrode layer 204. In such examples, portions of the first bottom electrode layer 204 can be removed via lithography (e.g., portions adjacent to the interconnect 306, etc.).

At block 1506, the second bottom electrode layer 902 is deposited on the first bottom electrode layer 204. For example, the second bottom electrode layer 902 is deposited via electroplating (e.g., electrochemical deposition, etc.) on the seed layer deposited on the first bottom electrode layer 204. In some such examples, the seed layer can be deposited on exposed regions of substrate layer 201 and the first bottom electrode layer 204 and the portions of the exposed regions of the first substrate layer 201 can be masked via a photomask. In some examples, after the second bottom electrode layer 902 has been deposited, the photomask can be removed (e.g., via ultra-violet light and a bath, etc.) and the exposed portions of the seed layer (e.g., the portions that were previously masked by the photoresist pattern, etc.) via etching. In other examples, the second bottom electrode layer 902 can be deposited in any other suitable manner (e.g., ALD, CVD, PVD, etc.). The second bottom electrode layer 902 can be composed of any suitable conductive material that oxidizes when exposed to an anodic oxidation bath (e.g., aluminum, tantalum, etc.). The point of fabrication after completion of block 1506 corresponds to the structure of the first intermediate stage 900 of FIG. 9.

At block 1508, the photoresist pattern 1002 is applied to the second bottom electrode layer 902. For example, the photoresist pattern 1002 can be formed with the openings 1004. The photoresist pattern 1002 can be deposited via lithography. In some examples, the photoresist pattern 1002 masks the second bottom electrode layer 902 such that the openings 1004 correspond to the portion of the second bottom electrode layer 902 that will be removed via negative etching during the execution of block 1510. In some examples, the photoresist pattern 1002 can be composed of a photo-sensitive material that becomes soluble when exposed to a particular wavelength of light. In other examples, the photoresist pattern 1002 and the openings 1004 can be formed by any other suitable means. The point of fabrication after the completion of block 1508 corresponds to the structure of the second intermediate stage 1000 of FIG. 10.

At block 1510, the second bottom electrode layer 902 is etched to form the openings 1104. For example, the second bottom electrode layer 902 can be etched to remove portions of the second bottom electrode layer 902 not masked by the photoresist pattern 1002. In some examples, the second bottom electrode layer 902 is etched via a timed etched such that the openings 1104 do not extend through the entire thickness of the second bottom electrode layer 902 to prevent direct contact (e.g., a short, etc.) between the electrodes of the capacitor structure 1400. In other examples, the openings 1104 can be formed in any other suitable manner.

At block 1512, the photoresist pattern 1002 is striped. For example, the photoresist pattern 1002 can be removed by exposing the photoresist pattern 1002 to a particular frequency of light to make the photoresist pattern 1002 soluble. In some such examples, after the exposure of the photoresist pattern 1002 to light, the photoresist pattern 1002 can be removed by applying a bath (e.g., a water bath, another solvent, etc.). In other examples, the photoresist pattern 1002 can be removed in any other suitable manner. The point of fabrication after completion of block 1510 corresponds to the structure of the third intermediate stage 1100 of FIG. 11.

At block 1514, the second bottom electrode layer 902 is exposed to an anodic oxidation bath to form the dielectric layer 1106. For example, the second bottom electrode layer 902 is exposed to an aqueous anodic oxidation bath with a neutral pH (e.g., a pH of greater than 5 but less than 7, etc.) and/or an acidic pH (e.g., a pH of less than 5, etc.) to form the dielectric layer 208. In some examples, if the second bottom electrode layer 902 is exposed to an acidic pH, the dielectric layer 1106 is a porous network of aluminum oxide. In some examples, if the second bottom electrode layer 902 is exposed to a neutral pH, the thin film 502 forms a dense network of aluminum oxide. The point of fabrication after completion of block 1514 corresponds to the structure of the fourth intermediate stage 1200 of FIG. 12.

At block 1516, the top electrode layer 1302 is deposited. For example, the top electrode layer 206 can be deposited via CVD and/or ALD. In other examples, the top electrode layer 1302 can be deposited via electroplating. In some such examples, a seed layer (not illustrated) is deposited on the dielectric layer 1106 prior to the plating of the top electrode layer 1302. In some examples, the top electrode layer is composed of TiN. In other examples, the top electrode layer 1302 can be composed of any suitable conductive material (e.g., copper, aluminum, silver, gold, etc.). In some examples, during the deposition of the top electrode layer 206, other components of the capacitor structure 1400 (e.g., exposed areas of the first substrate layer 201, etc.) can be masked by the photoresist pattern 1202 to prevent the material of the top electrode layer 1302 from being deposited thereon. The point of fabrication after completion of block 1516 corresponds to the structure of the fifth intermediate stage 1300 of FIG. 13.

At block 1518, another substrate layer is deposited. For example, the second substrate layer 216 can be deposited on the top electrode layer 206 and other components of the capacitor structure (e.g., the third via 210C, exposed portions of the first substrate layer 201, etc.). In some examples, the second substrate layer 216 can be composed of a non-conductive (e.g., epoxy, etc.) and/or organic material. At block 816, the first via 210A and the second via 210B are formed in the second substrate layer 216 and are in contact with the top electrode layer 206. For example, the vias 210A, 210B can be formed by negative manufacturing (e.g., laser drilling, etc.), depositing a resist layer on unremoved portions of the second substrate layer, and plating a conductive material (e.g., copper, etc.) within the openings. In other examples, the additional vias can be formed by any other suitable manufacturing process. The point of fabrication after completion of block 1520 corresponds to the capacitor structure 1400 of FIG. 14. The operations 1500 end.

FIG. 16A is a cross-sectional view of an example first capacitor configuration 1600 that can be used in conjunction with the thin film capacitors 202, 1402 of FIGS. 2 and 14, respectively, taken along the cross-section A-A line of FIG. 2. The first capacitor configuration includes an example first opening 1602A, an example second opening 1602B, and an example third opening 1602C. In the illustrated example of FIG. 16A, the openings 1602A, 1602B, 1602C are formed within the example first material 1604 (e.g., a first electrode material, etc.). and are filed with an example second material 1606 (e.g., a second electrode material, etc.). In the illustrated example of FIG. 16A, each of the openings 1602A, 1602B, 1602C are lined with an example third material (e.g., a dielectric material, etc.).

In the illustrated example of FIG. 16A, the openings 1602A, 1602B, 1602C are rectangular trenches. As used herein, the term “trench” refers to an opening in a material that is substantially longer than it is wide. The openings 1602A, 1602B, 1602C have an example width 1609 (e.g., a dimension along the X-axis, etc.), an example length 1610 (e.g., a dimension along the Y-axis, etc.), and the example depth 218 of FIG. 2. The openings 1602A, 1602B, 1602C described herein have an aspect ratio of greater than 1. The aspect ratio refers to the ratio of the depth 218 of the opening to the width 1609 of the opening. Increasing the aspect ratio of the openings 1602A, 1602B, 1602C increases the contact area between the materials 1604, 1606, which increases the capacitance density of the resulting capacitor.

FIG. 16B is a cross-sectional view of an example second capacitor configuration 1611 that can be used in conjunction with the thin film capacitors 200, 1402 of FIGS. 2 and 14, respectively. The second capacitor configuration 1611 includes an example first opening 1612A, an example second opening 1612B, an example third opening 1612C, an example fourth opening 1612D, an example fifth opening 1612E, an example sixth opening 1612F, an example seventh opening 1612G, an example eighth opening 1612H, and an example ninth opening 1612I. In the illustrated example of FIG. 16B, the openings 1612A-1612I are circular and have a radius of the example width 1609. The openings 1612A-1612I described herein have aspect ratio of greater than 1. In the illustrated example of FIG. 16B, the openings 1612A-1612I are arranged in a grid (e.g., a 2-dimensional matrix, etc.) and are evenly spaced and distributed along the Y-axis and the X-axis. Increasing the aspect ratio of the openings 1612A-1612I increases the contact area between the materials 1604, 1606, which increases the capacitance density of the resulting capacitor.

FIG. 16C is a cross-sectional view of an example first capacitor configuration 1614 that can be used in conjunction with the thin film capacitors 202, 1402 of FIGS. 2-15. The third capacitor configuration 1614 includes an example first opening 1616A, an example second opening 1616B, an example third opening 1616C, an example fourth opening 1616D, an example fifth opening 1616E, an example sixth opening 1616F, an example seventh opening 1616G, an example eighth opening 1616H, and an example ninth opening 1616I. In the illustrated example of FIG. 16C, the openings 1616A-1616I are squares and have a side length of the example width 1609. The openings 1616A-1616I described herein have an aspect ratio of greater than 1. In the illustrated example of FIG. 16C, the openings 1616A-1616I are arranged in a grid (e.g., a 2-dimensional matrix, etc.) and are evenly spaced and distributed along the Y-axis and the X-axis. Increasing the aspect ratio of the openings 1616A-1616I increases the contact area between the materials 1604, 1606, which increases the capacitance density of the resulting capacitor.

The first material 1604 of FIGS. 12A-12C is associated with one or more of the materials associated with bottom electrode (e.g., the first bottom electrode layer 204, etc.). The second material 1606 of FIGS. 12A-12C is associated with the conductive one or more of the materials associated with top electrode (e.g., the top electrode layer 206 of FIG. 2-7, 9-14, etc.). The third material 1608 of FIGS. 12A-12C is associated with one or more of the materials associated with the dielectric layer (e.g., the dielectric layer 208, etc.). In other examples, the first material 1604 can be associated with the top electrode and the second material 1606 can be associated with the bottom electrode. Generally, the configurations 1600, 1611, 1614 of FIGS. 12A-12C offer substantially equal capacitor densities for thin film capacitors including the configurations 1600, 1611, 1614. Accordingly, increasing the aspect ratio of the openings of the configurations 1600, 1611, 1614 or decreasing the spacing between respective ones of the openings of the configurations 1600, 1611, 1614 increases the capacitance density of the thin film capacitors regardless of the geometry of the openings of the configurations 1600, 1611, 1614.

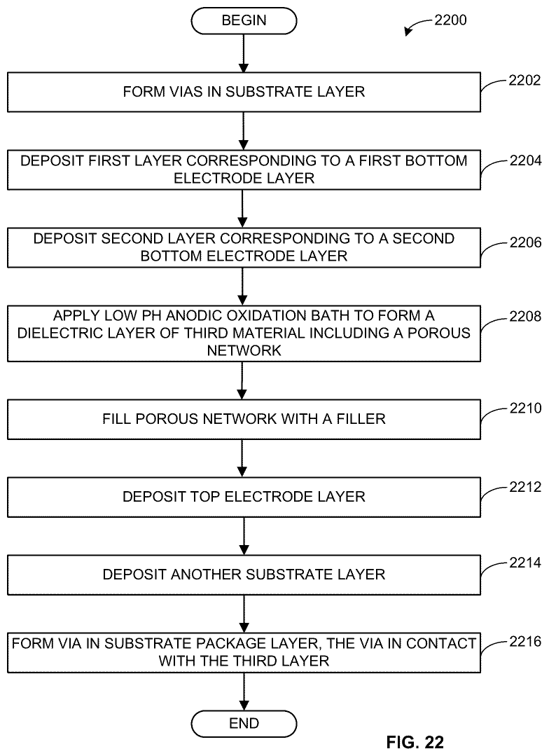

FIGS. 17-21 depict a plurality of intermediate stages in an example process to manufacture another capacitor structure 2100, similar to the capacitor structure 200 of FIG. 2, implemented in accordance. It should be appreciated that other processes can be used in the manufacturing of the capacitor structure of FIGS. 17-21. Example operations to manufacture the capacitor structure of FIGS. 17-21 are described below in conjunction with FIG. 22.

FIG. 17 is a cross-sectional view of an example first intermediate stage 1700 of the fabrication of the capacitor structure 2100 of FIG. 21. In the illustrated example of FIG. 17, an example substrate layer 1702 (e.g., similar to the first substrate layer 201 of FIG. 2, etc.) has an example first layer 1704 deposited thereon. The first layer 1704 can be deposited via electrochemical plating. In other examples, the first layer 1704 can be deposited by any other suitable process. In the illustrated example of FIG. 17, the first layer 1704 is patterned (e.g., via a resist process, via etching, via lithography, etc.) to form the example first bottom electrode layer 1708 and example interconnects 1710A, 1710B for the vias 1706C and the via 1706D, respectively. In some examples, the interconnects 1710A, 1710B and/or the vias 1706C, 1706D can be absent. The example first layer 1704 is composed of copper. In other examples, the first layer 1704 can be composed of any other suitable conductive material.

FIG. 18 is a cross-sectional view of an example second intermediate stage 1800 of the fabrication of the capacitor structure 2100 of FIG. 21. In the illustrated example of FIG. 18, an example second bottom electrode layer 1802 on the first bottom electrode layer 1708 of FIG. 18. For example, the second bottom electrode layer 1802 can be deposited via CVD deposition, PVD deposition, and/or electroplating. In other examples, the second bottom electrode layer 1802 can be deposited by any other suitable process. In the illustrated example of FIG. 18, the second bottom electrode layer 1802 is composed of aluminum. In other examples, the second bottom electrode layer 1802 can be composed of any suitable material that forms a dielectric oxide when anodically oxidized and is conductive in an elemental form (e.g., tantalum, etc.).

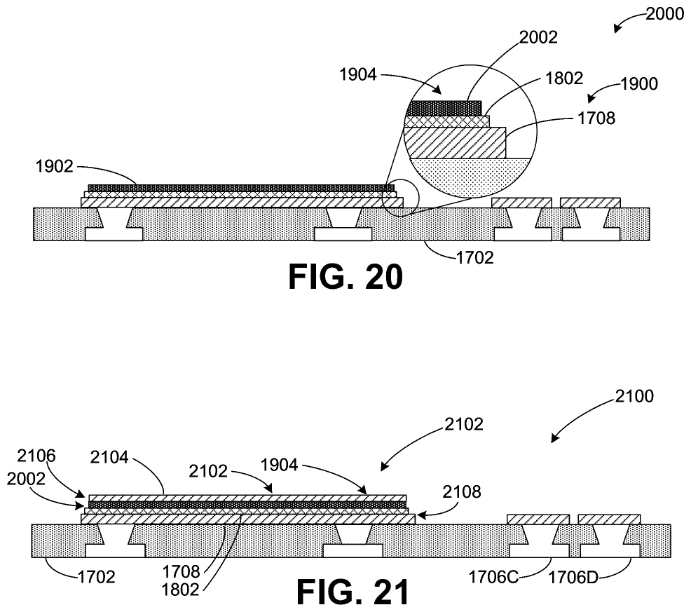

FIG. 19 is a cross-sectional view of an example third intermediate stage 1900 of the fabrication of the capacitor structure 2100 of FIG. 21. In the illustrated example of FIG. 19, an example dielectric layer 1902 has been formed on the second bottom electrode layer 1802. In the illustrated example of FIG. 20, the dielectric layer 1902 includes an example porous network 1904. For example, the dielectric layer 1902 can be formed by exposing (e.g., via wet etching, etc.) the second bottom electrode layer 1802 to an electric field in an aqueous anodic oxidation bath with an acidic pH (e.g., a pH of less than 5, etc.). For example, the aqueous anodic oxidation bath can be composed of water (e.g., distilled H₂O, etc.) with significantly more H⁺ ions than OH ions and an electrical current flowing through. The aqueous anodic oxidation strips electrons from the second bottom electrode layer 1802, which causes the formation of aluminum oxide via the following chemical half-reaction at the anode:

$$2 A l + 3 {H}_{2} O \to {Al}_{2} {O}_{2} + 6 {H}^{+} + 6 {e}^{-}$$

In the illustrated example of FIG. 19, the comparatively low pH of the aqueous anodic oxidation bath causes the pores of the porous network 1904 to be irregular (e.g., disorganized, unstructured, random, etc.).

FIG. 20 is a cross-sectional view of an example fourth intermediate stage 2000 of the fabrication of the capacitor structure 2100 of FIG. 21. In the illustrated example of FIG. 20, pores of the porous network 1904 have been filled with an example via an example filler 2002. In the capacitor structure 2100 described in FIGS. 17-21, the filler 2002 acts as a first portion of the top electrode of a capacitor of the capacitor structure 2100. In some examples, the filler 2002 can be conformally deposited within the porous network 1904 via ALD. In the illustrated example of FIG. 20, the filler 2002 fills the openings of the porous network 1904 and a thin top layer on top of the porous network 1904. In some such examples, the filler 2002 can be composed of a titanium-nickel alloy and/or any other suitable conductive material. In other examples, the filler 2002 can be a conductive polymer paste (e.g., a silver polymer paste, etc.) deposited via printing. In the illustrated example of FIGS. 20 and 21, the porous network 1904 is formed such that a layer of aluminum oxide separates the filler 2002 from the second bottom electrode layer 1802, which prevents direct contact between the filler 2002 (e.g., part of the top electrode, etc.) and the second bottom electrode layer 1802 (e.g., part of the bottom electrode, etc.).

FIG. 21 is a cross-sectional view of the example capacitor structure 2100 manufactured via the intermediate stages 1800, 1900, 2000 of FIGS. 18-20. In the illustrated example of FIG. 21, the capacitor structure 2100 includes an example top electrode layer 2104 deposited on the porous network 1904 of FIG. 20. The top electrode layer 2104 can be deposited via electroplating. In some such examples, a seed layer (not illustrated) is deposited on the porous network 1904 prior to the plating of the top electrode layer 2104, etc. In other examples, the top electrode layer 2104 can be deposited via CVD and/or PVD. The top electrode layer 2104 can be composed of any suitable conductive material (e.g., copper, aluminum, silver, gold, etc.). In some examples, during the deposition of the top electrode layer 2104, other components of the capacitor structure 2100 (e.g., the third vias 1706C, the fourth via 1706D, exposed areas of the substrate layer 1702, etc.) can be masked via a resist to prevent the material of the top electrode layer 2104 from being deposited thereon.

In the illustrated example of FIG. 21, the capacitor structure 2100 includes an example thin film capacitor 2102, which includes an example top electrode 2106, an example bottom electrode 2108, and the example dielectric layer 1902 of FIG. 20. In the illustrated example of FIG. 21, the top electrode 2106 is defined by the top electrode layer 2104 and the filler 2002, and the bottom electrode 2108 is defined by the first bottom electrode layer 1708 and the second bottom electrode layer 1802. The top electrode 2106 and the bottom electrode 2108 are separated via the dielectric layer 1902. The surface area of the thin film capacitor 2102 (e.g., a driving parameter of the capacitance density, etc.) is equal to the sum of the contact area between filler 2002 and the porous network 1904 of the dielectric layer 1902, the contact area between the top electrode layer 2104 and the porous network 1904 of the dielectric layer 1902. Accordingly, the thin film capacitor 2102 offers substantially higher capacitance than a strictly planar thin film capacitor of the same footprint.

FIG. 22 is a flow diagram of example operations 2200 that can be used to manufacture the capacitor structure 2100 of FIG. 21. Although the example method of manufacture is described with reference to the flowchart illustrated in FIG. 22, many other methods may alternatively be used. For example, the order of execution of the blocks may be changed, and/or some of the blocks described may be combined, divided, re-arranged, omitted, eliminated, and/or implemented in any other way.

The example operations 2200 begin at block 2202, at which the vias 1706A, 1706B, 1706C, 1706D are formed within the substrate layer 1702. For example, the vias 1706A, 1706B, 1706C, 1706D can be formed by negative manufacturing (e.g., laser drilling, etc.) the substrate layer to form openings corresponding to the vias 1706A, 1706B, 1706C, 1706D, depositing a resist layer on unremoved portions of the substrate layer 1702, and plating a conductive material (e.g., copper, etc.) within the openings. In other examples, the vias 1706A, 1706B, 1706C, 1706D can be formed by any other suitable manufacturing process. In other examples, some or all of the vias 1706A, 1706B, 1706C, 1706D can be absent.

At block 2204, the first layer 1704 is deposited on the substrate layer 1702 to form the first bottom electrode layer 1708. For example, the first layer 1704 can be deposited via electroplating. In some such examples, a seed layer and a photoresist pattern can be deposited on the substrate layer 1702 prior to the deposition of the first layer 1704. In some examples, the seed layer can be used as a catalyst to electroplate the first layer 1704. In some examples, after the first layer 1704 has been deposited, the seed layer and/or the resist layer can be removed (e.g., via etching, via dry film resist striping, etc.). In some such examples, the first layer 1704 is plating in a manner that forms the interconnects 1710A, 1710B, and the first bottom electrode layer 1708. Additionally or alternatively, the first layer 1704 can be deposited over the entire substrate layer 1702 and a photoresist mask can be deposited after the first layer 1704. In such examples, portions of the first layer 1704 can be removed via lithography (e.g., a portion of the first layer 1704 between the first bottom electrode layer 1708 and the first interconnect 1710A, a portion of the first layer 1704 between the interconnects 1710A, 1710B, etc.) to form the interconnects 1710A, 1710B and the first bottom electrode layer 1708. The point of fabrication after completion of block 2204 corresponds to the structure of intermediate stage 1700 of FIG. 17.

At block 2206, the second bottom electrode layer 1802 is deposited on the first bottom electrode layer 1708. For example, the second bottom electrode layer 1802 can be deposited via CVD and/or electroplating. In some examples, portions of the substrate layer 1702 and/or the first layer 1704 that do not correspond to the second bottom electrode layer 1802 can be masked to ensure that the second bottom electrode layer 1802 is only deposited on the first bottom electrode layer 1708. In some examples, the second bottom electrode layer 1802 can be composed of any suitable conductive material that forms a dielectric oxide when anodically oxidized (e.g., aluminum, tantalum, etc.). The point of fabrication after completion of block 2206 corresponds to the structure of intermediate stage 1800 of FIG. 18.

At block 2208, a low pH anodic oxidation bath is applied to form the dielectric layer 1902 including the porous network 1904. For example, the dielectric layer 1902 can be formed by exposing (e.g., via wet etching, etc.) the second bottom electrode layer 1802 to an aqueous anodic oxidation bath with an acidic pH (e.g., a pH of less than 5, etc.). In some examples, the aqueous anodic oxidation bath can be composed of water (e.g., distilled H₂O, etc.) with significantly more H⁺ ions than OH ions and an electrical current flowing through. The aqueous anodic oxidation strips electrons from the second bottom electrode layer 1802, which causes the formation of aluminum oxide. The comparatively low pH of the aqueous anodic oxidation bath causes the pores of the porous network 1904 to be irregular (e.g., disorganized, unstructured, random, etc.). The point of fabrication after completion of block 2208 corresponds to the structure of intermediate stage 2000 of FIG. 20.

At block 2210, the porous network 1904 is filled with a filler 2002. For example, the filler 2002 can be conformally deposited within the porous network 1904 via ALD. In some such examples, the filler 2002 can be composed of a titanium-nickel alloy and/or any other suitable conductive material. Additionally or alternatively, the filler 2002 can be a conductive polymer paste (e.g., a silver polymer paste, etc.) deposited via printing. In some examples, the filler 2002 fills the openings of the porous network 1904 and a thin top layer on top of the porous network 1904. In some examples, the filler 2002 acts as a first portion of the top electrode of a capacitor of the capacitor structure 2100. The point of fabrication after the completion of block 2210 corresponds to the structure of the capacitor structure 2100.

At block 2212, the top electrode layer 2104 is deposited. For example, the top electrode layer 2104 can be deposited via electroplating. In some such examples, a seed layer (not illustrated) is deposited on the porous network 1904 before the plating of the top electrode layer 2104, etc. In other examples, the top electrode layer 2104 can be deposited via CVD and/or PVD. The top electrode layer 2104 can be composed of any suitable conductive material (e.g., copper, aluminum, silver, gold, etc.). In some examples, during the deposition of the top electrode layer 2104, other components of the capacitor structure 2100 (e.g., the third vias 1706C, the fourth via 1706D, exposed areas of the substrate layer 1702, etc.) can be masked to prevent the material of the top electrode layer 2104 from being deposited thereon. The point of fabrication after completion of block 2212 corresponds to the capacitor structure 2100 of FIG. 21.

At block 2214, another substrate layer is deposited. For example, a second substrate layer (e.g., similar to the substrate layer 216 of FIG. 2, etc.) can be deposited on the top electrode layer 2104 and other components of the assembly (e.g., the vias 1706A, 1706B, exposed portions of the substrate layer 1702, etc.). In some examples, the second substrate layer can be composed of a non-conductive (e.g., epoxy, etc.) and/or organic material. At block 2216, additional vias are deposited on the second substrate layer in contact with the top electrode layer 2104. For example, the additional vias can be formed by negative manufacturing (e.g., laser drilling, etc.), depositing a resist layer on unremoved portions of the second substrate layer, and plating a conductive material (e.g., copper, etc.) within the openings. In other examples, the additional vias can be formed by any other suitable manufacturing process. The operations 2200 end.

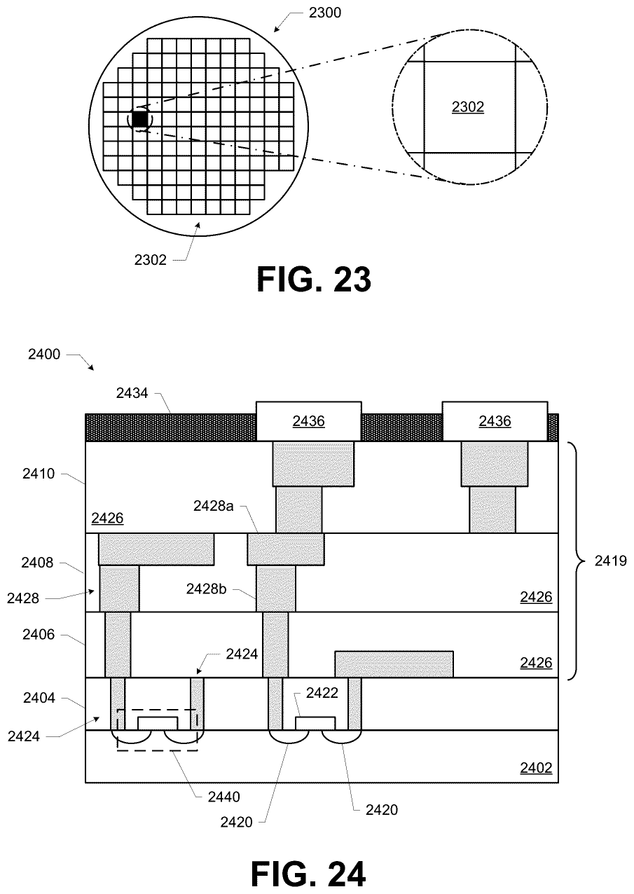

The example capacitor structures 200, 1400, 2100 disclosed herein may be included in any suitable electronic component. FIGS. 23-26 illustrate various examples of apparatus that may include or be included in the capacitor structures 200, 1400, 2100 disclosed herein.

FIG. 23 is a top view of a wafer 2300 and dies 2302 that may be included in the capacitor structures 200, 1400, 2100. The wafer 2300 may be composed of semiconductor material and may include one or more dies 2302 having IC structures formed on a surface of the wafer 2300. Each of the dies 2302 may be a repeating unit of a semiconductor product that includes any suitable IC. After the fabrication of the semiconductor product is complete, the wafer 2300 may undergo a singulation process in which the dies 2302 are separated from one another to provide discrete “chips” of the semiconductor product. The die 2302 may include one or more transistors (e.g., some of the transistors 2440 of FIG. 24, discussed below), supporting circuitry to route electrical signals to the transistors, passive components (e.g., signal traces, resistors, capacitors, or inductors), and/or any other IC components. In some examples, the wafer 2300 or the die 2302 may include a memory device (e.g., a random access memory (RAM) device, such as a static RAM (SRAM) device, a magnetic RAM (MRAM) device, a resistive RAM (RRAM) device, a conductive-bridging RAM (CBRAM) device, etc.), a logic device (e.g., an AND, OR, NAND, or NOR gate), or any other suitable circuit element. Multiple ones of these devices may be combined on a single die 2302. For example, a memory array formed by multiple memory devices may be formed on a same die 2302 as processor circuitry or other logic that is configured to store information in the memory devices or execute instructions stored in the memory array. The example capacitor structures 200, 1400, 2100 disclosed herein may be manufactured using a die-to-wafer assembly technique in which some dies 106, 108 are attached to a wafer 2300 that include others of the dies 106, 108, and the wafer 2300 is subsequently singulated.

FIG. 24 is a cross-sectional side view of an IC device 2400 that may be included in the example capacitor structures 200, 1400, 2100 (e.g., in any one of the package substrate 110). One or more of the IC devices 2400 may be included in one or more dies 2302 (FIG. 23). The IC device 2400 may be formed on a die substrate 2402 (e.g., the wafer 2300 of FIG. 23) and may be included in a die (e.g., the die 2302 of FIG. 23). The die substrate 2402 may be a semiconductor substrate composed of semiconductor material systems including, for example, n-type or p-type materials systems (or a combination of both). The die substrate 2402 may include, for example, a crystalline substrate formed using a bulk silicon or a silicon-on-insulator (SOI) substructure. In some examples, the die substrate 2402 may be formed using alternative materials, which may or may not be combined with silicon, that include but are not limited to germanium, indium antimonide, lead telluride, indium arsenide, indium phosphide, gallium arsenide, or gallium antimonide. Further materials classified as group II-VI, III-V, or IV may also be used to form the die substrate 2402. Although a few examples of materials from which the die substrate 2402 may be formed are described here, any material that may serve as a foundation for an IC device 2400 may be used. The die substrate 2402 may be part of a singulated die (e.g., the dies 2302 of FIG. 23) or a wafer (e.g., the wafer 2300 of FIG. 23).

The IC device 2400 may include one or more device layers 2404 disposed on the die substrate 2402. The device layer 2404 may include features of one or more transistors 2440 (e.g., metal oxide semiconductor field-effect transistors (MOSFETs)) formed on the die substrate 2402. The device layer 2404 may include, for example, one or more source and/or drain (S/D) regions 2420, a gate 2422 to control current flow in the transistors 2440 between the S/D regions 2420, and one or more S/D contacts 2424 to route electrical signals to/from the S/D regions 2420. The transistors 2440 may include additional features not depicted for the sake of clarity, such as device isolation regions, gate contacts, and the like. The transistors 2440 are not limited to the type and configuration depicted in FIG. 24 and may include a wide variety of other types and configurations such as, for example, planar transistors, non-planar transistors, or a combination of both. Non-planar transistors may include FinFET transistors, such as double-gate transistors or tri-gate transistors, and wrap-around or all-around gate transistors, such as nanoribbon and nanowire transistors.

Each transistor 2440 may include a gate 2422 formed of at least two layers, a gate dielectric and a gate electrode. The gate dielectric may include one layer or a stack of layers. The one or more layers may include silicon oxide, silicon dioxide, silicon carbide, and/or a high-k dielectric material. The high-k dielectric material may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some examples, an annealing process may be carried out on the gate dielectric to improve its quality when a high-k material is used.

The gate electrode may be formed on the gate dielectric and may include at least one p-type work function metal or n-type work function metal, depending on whether the transistor 2440 is to be a p-type metal oxide semiconductor (PMOS) or an n-type metal oxide semiconductor (NMOS) transistor. In some implementations, the gate electrode may consist of a stack of two or more metal layers, where one or more metal layers are work function metal layers and at least one metal layer is a fill metal layer. Further metal layers may be included for other purposes, such as a barrier layer. For a PMOS transistor, metals that may be used for the gate electrode include, but are not limited to, ruthenium, palladium, platinum, cobalt, nickel, conductive metal oxides (e.g., ruthenium oxide), and any of the metals discussed below with reference to an NMOS transistor (e.g., for work function tuning). For an NMOS transistor, metals that may be used for the gate electrode include, but are not limited to, hafnium, zirconium, titanium, tantalum, aluminum, alloys of these metals, carbides of these metals (e.g., hafnium carbide, zirconium carbide, titanium carbide, tantalum carbide, and aluminum carbide), and any of the metals discussed above with reference to a PMOS transistor (e.g., for work function tuning).

In some examples, when viewed as a cross-section of the transistor 2440 along the source-channel-drain direction, the gate electrode may consist of a U-shaped structure that includes a bottom portion substantially parallel to the surface of the die substrate 2402 and two sidewall portions that are substantially perpendicular to the top surface of the die substrate 2402. In other examples, at least one of the metal layers that form the gate electrode may simply be a planar layer that is substantially parallel to the top surface of the die substrate 2402 and does not include sidewall portions substantially perpendicular to the top surface of the die substrate 2402. In other examples, the gate electrode may consist of a combination of U-shaped structures and planar, non-U-shaped structures. For example, the gate electrode may consist of one or more U-shaped metal layers formed atop one or more planar, non-U-shaped layers.

In some examples, a pair of sidewall spacers may be formed on opposing sides of the gate stack to bracket the gate stack. The sidewall spacers may be formed from materials such as silicon nitride, silicon oxide, silicon carbide, silicon nitride doped with carbon, and silicon oxynitride. Processes for forming sidewall spacers are well known in the art and generally include deposition and etching process steps. In some examples, a plurality of spacer pairs may be used; for instance, two pairs, three pairs, or four pairs of sidewall spacers may be formed on opposing sides of the gate stack.

The S/D regions 2420 may be formed within the die substrate 2402 adjacent to the gate 2422 of each transistor 2440. The S/D regions 2420 may be formed using an implantation/diffusion process or an etching/deposition process, for example. In the former process, dopants such as boron, aluminum, antimony, phosphorous, or arsenic may be ion-implanted into the die substrate 2402 to form the S/D regions 2420. An annealing process that activates the dopants and causes them to diffuse farther into the die substrate 2402 may follow the ion-implantation process. In the latter process, the die substrate 2402 may first be etched to form recesses at the locations of the S/D regions 2420. An epitaxial deposition process may then be carried out to fill the recesses with material that is used to fabricate the S/D regions 2420. In some implementations, the S/D regions 2420 may be fabricated using a silicon alloy such as silicon germanium or silicon carbide. In some examples, the epitaxially deposited silicon alloy may be doped in situ with dopants such as boron, arsenic, or phosphorous. In some examples, the S/D regions 2420 may be formed using one or more alternate semiconductor materials such as germanium or a group III-V material or alloy. In further examples, one or more layers of metal and/or metal alloys may be used to form the S/D regions 2420.

Electrical signals, such as power and/or input/output (I/O) signals, may be routed to and/or from the devices (e.g., transistors 2440) of the device layer 2404 through one or more interconnect layers disposed on the device layer 2404 (illustrated in FIG. 24 as interconnect layers 2406-2410). For example, electrically conductive features of the device layer 2404 (e.g., the gate 2422 and the S/D contacts 2424) may be electrically coupled with the interconnect structures 2428 of the interconnect layers 2406-2410. The one or more interconnect layers 2406-2410 may form a metallization stack (also referred to as an “ILD stack”) 2419 of the IC device 2400.

The interconnect structures 2428 may be arranged within the interconnect layers 2406-2410 to route electrical signals according to a wide variety of designs (in particular, the arrangement is not limited to the particular configuration of interconnect structures 2428 depicted in FIG. 24). Although a particular number of interconnect layers 2406-2410 is depicted in FIG. 24, examples of the present disclosure include IC devices having more or fewer interconnect layers than depicted.

In some examples, the interconnect structures 2428 may include lines 2428a and/or vias 2428b filled with an electrically conductive material such as a metal. The lines 2428a may be arranged to route electrical signals in a direction of a plane that is substantially parallel with a surface of the die substrate 2402 upon which the device layer 2404 is formed. For example, the lines 2428a may route electrical signals in a direction in and out of the page from the perspective of FIG. 24. The vias 2428b may be arranged to route electrical signals in a direction of a plane that is substantially perpendicular to the surface of the die substrate 2402 upon which the device layer 2404 is formed. In some examples, the vias 2428b may electrically couple lines 2428a of different interconnect layers 2406-2410 together.

The interconnect layers 2406-2410 may include a dielectric material 2426 disposed between the interconnect structures 2428, as shown in FIG. 24. In some examples, the dielectric material 2426 disposed between the interconnect structures 2428 in different ones of the interconnect layers 2406-2410 may have different compositions; in other examples, the composition of the dielectric material 2426 between different interconnect layers 2406-2410 may be the same.

A first interconnect layer 2406 (referred to as Metal 1 or “M1”) may be formed directly on the device layer 2404. In some examples, the first interconnect layer 2406 may include lines 2428a and/or vias 2428b, as shown. The lines 2428a of the first interconnect layer 2406 may be coupled with contacts (e.g., the S/D contacts 2424) of the device layer 2404.

A second interconnect layer 2408 (referred to as Metal 2 or “M2”) may be formed directly on the first interconnect layer 2406. In some examples, the second interconnect layer 2408 may include vias 2428b to couple the lines 2428a of the second interconnect layer 2408 with the lines 2428a of the first interconnect layer 2406. Although the lines 2428a and the vias 2428b are structurally delineated with a line within each interconnect layer (e.g., within the second interconnect layer 2408) for the sake of clarity, the lines 2428a and the vias 2428b may be structurally and/or materially contiguous (e.g., simultaneously filled during a dual-damascene process) in some examples.

A third interconnect layer 2410 (referred to as Metal 3 or “M3”) (and additional interconnect layers, as desired) may be formed in succession on the second interconnect layer 2408 according to similar techniques and configurations described in connection with the second interconnect layer 2408 or the first interconnect layer 2406. In some examples, the interconnect layers that are “higher up” in the metallization stack 2419 in the IC device 2400 (i.e., further away from the device layer 2404) may be thicker.

The IC device 2400 may include a solder resist material 2434 (e.g., polyimide or similar material) and one or more conductive contacts 2436 formed on the interconnect layers 2406-2410. In FIG. 24, the conductive contacts 2436 are illustrated as taking the form of bond pads. The conductive contacts 2436 may be electrically coupled with the interconnect structures 2428 and configured to route the electrical signals of the transistor(s) 2440 to other external devices. For example, solder bonds may be formed on the one or more conductive contacts 2436 to mechanically and/or electrically couple a chip including the IC device 2400 with another component (e.g., a circuit board). The IC device 2400 may include additional or alternate structures to route the electrical signals from the interconnect layers 2406-2410; for example, the conductive contacts 2436 may include other analogous features (e.g., posts) that route the electrical signals to external components.

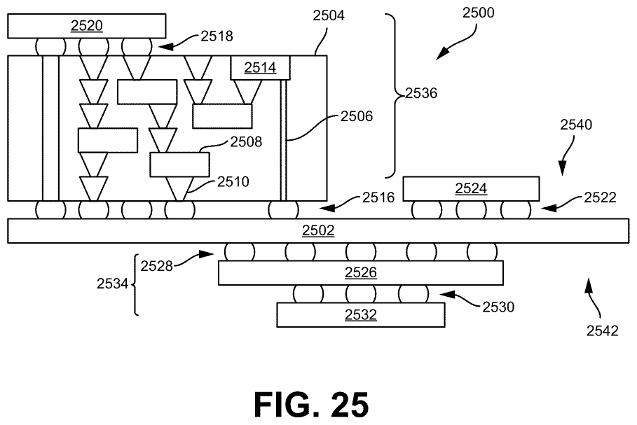

FIG. 25 is a cross-sectional side view of an IC device assembly 2500 that may include the capacitor structures 200, 1400, 2100 disclosed herein. In some examples, the IC device assembly corresponds to the capacitor structures 200, 1400, 2100. The IC device assembly 2500 includes a number of components disposed on a circuit board 2502 (which may be, for example, a motherboard). The IC device assembly 2500 includes components disposed on a first face 2540 of the circuit board 2502 and an opposing second face 2542 of the circuit board 2502; generally, components may be disposed on one or both faces 2540 and 2542. Any of the IC packages discussed below with reference to the IC device assembly 2500 may take the form of the example capacitor structures 200, 1400, 2100 of FIGS. 2, 14, and 21.

In some examples, the circuit board 2502 may be a printed circuit board (PCB) including multiple metal layers separated from one another by layers of dielectric material and interconnected by electrically conductive vias. Any one or more of the metal layers may be formed in a desired circuit pattern to route electrical signals (optionally in conjunction with other metal layers) between the components coupled to the circuit board 2502. In other examples, the circuit board 2502 may be a non-PCB substrate. In some examples, the circuit board 2502 may be, for example, the circuit board 102 of FIG. 1.

The IC device assembly 2500 illustrated in FIG. 25 includes a package-on-interposer structure 2536 coupled to the first face 2540 of the circuit board 2502 by coupling components 2516. The coupling components 2516 may electrically and mechanically couple the package-on-interposer structure 2536 to the circuit board 2502, and may include solder balls (as shown in FIG. 25), male and female portions of a socket, an adhesive, an underfill material, and/or any other suitable electrical and/or mechanical coupling structure.

The package-on-interposer structure 2536 may include an IC package 2520 coupled to an interposer 2504 by coupling components 2518. The coupling components 2518 may take any suitable form for the application, such as the forms discussed above with reference to the coupling components 2516. Although a single IC package 2520 is shown in FIG. 25, multiple IC packages may be coupled to the interposer 2504; indeed, additional interposers may be coupled to the interposer 2504. The interposer 2504 may provide an intervening substrate used to bridge the circuit board 2502 and the IC package 2520. The IC package 2520 may be or include, for example, a die (the die substrate 2402 of FIG. 24), an IC device (e.g., the IC device 2500 of FIG. 25), or any other suitable component. Generally, the interposer 2504 may spread a connection to a wider pitch or reroute a connection to a different connection. For example, the interposer 2504 may couple the IC package 2520 (e.g., a die) to a set of BGA conductive contacts of the coupling components 2516 for coupling to the circuit board 2502. In the example illustrated in FIG. 25, the IC package 2520 and the circuit board 2502 are attached to opposing sides of the interposer 2504; in other examples, the IC package 2520 and the circuit board 2502 may be attached to a same side of the interposer 2504. In some examples, three or more components may be interconnected by way of the interposer 2504.

In some examples, the interposer 2504 may be formed as a PCB, including multiple metal layers separated from one another by layers of dielectric material and interconnected by electrically conductive vias. In some examples, the interposer 2504 may be formed of an epoxy resin, a fiberglass-reinforced epoxy resin, an epoxy resin with inorganic fillers, a ceramic material, or a polymer material such as polyimide. In some examples, the interposer 2504 may be formed of alternate rigid or flexible materials that may include the same materials described above for use in a semiconductor substrate, such as silicon, germanium, and other group III-V and group IV materials. The interposer 2504 may include metal interconnects 2508 and vias 2510, including but not limited to through-silicon vias (TSVs) 2506. The interposer 2504 may further include embedded devices 2514, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio frequency devices, power amplifiers, power management devices, antennas, arrays, sensors, and microelectromechanical systems (MEMS) devices may also be formed on the interposer 2504. The package-on-interposer structure 2536 may take the form of any of the package-on-interposer structures known in the art.

The IC device assembly 2500 may include an IC package 2524 coupled to the first face 2540 of the circuit board 2502 by coupling components 2522. The coupling components 2522 may take the form of any of the examples discussed above with reference to the coupling components 2516, and the IC package 2524 may take the form of any of the examples discussed above with reference to the IC package 2520.

The IC device assembly 2500 illustrated in FIG. 25 includes a package-on-package structure 2534 coupled to the second face 2542 of the circuit board 2502 by coupling components 2528. The package-on-package structure 2534 may include a first IC package 2526 and a second IC package 2532 coupled together by coupling components 2530 such that the first IC package 2526 is disposed between the circuit board 2502 and the second IC package 2532. The coupling components 2528, 2530 may take the form of any of the examples of the coupling components 2516 discussed above, and the IC packages 2526, 2532 may take the form of any of the examples of the IC package 2520 discussed above. The package-on-package structure 2534 may be configured in accordance with any of the package-on-package structures known in the art.

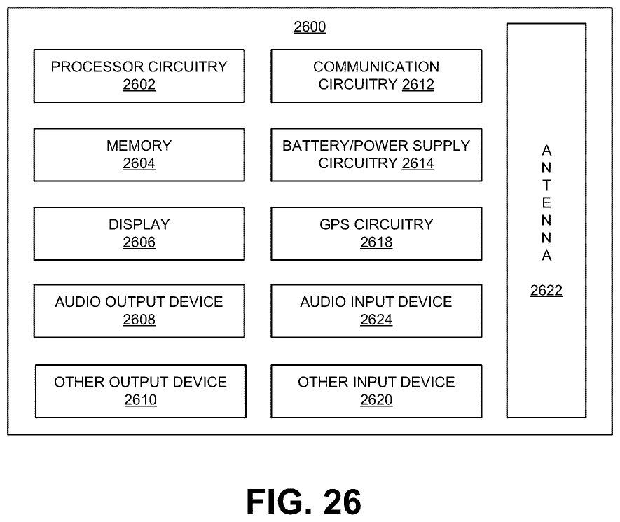

FIG. 26 is a block diagram of an example electrical device 2600 that may include one or more of the example capacitor structures 200, 1400, 2100 of FIGS. 2, 14, and 21. For example, any suitable ones of the components of the electrical device 2600 may include one or more of the device assemblies 2600, IC devices 2500, or die substrate 2402 disclosed herein, and may be arranged in the example capacitor structures 200, 1400, 2100. A number of components are illustrated in FIG. 26 as included in the electrical device 2600, but any one or more of these components may be omitted or duplicated, as suitable for the application. In some examples, some or all of the components included in the electrical device 2600 may be attached to one or more motherboards. In some examples, some or all of these components are fabricated onto a single system-on-a-chip (SoC) die.

Additionally, in various examples, the electrical device 2600 may not include one or more of the components illustrated in FIG. 26, but the electrical device 2600 may include interface circuitry for coupling to the one or more components. For example, the electrical device 2600 may not include a display 2606, but may include display interface circuitry (e.g., a connector and driver circuitry) to which a display 2606 may be coupled. In another set of examples, the electrical device 2600 may not include an audio input device 2624 (e.g., microphone) or an audio output device 2608 (e.g., a speaker, a headset, earbuds, etc.), but may include audio input or output device interface circuitry (e.g., connectors and supporting circuitry) to which an audio input device 2624 or audio output device 2608 may be coupled.

The electrical device 2600 may include a processor circuitry 2602 (e.g., one or more processing devices). As used herein, the term “processing device” or “processor” may refer to any device or portion of a device that processes electronic data from registers and/or memory to transform that electronic data into other electronic data that may be stored in registers and/or memory. The processor circuitry 2602 may include one or more digital signal processors (DSPs), application-specific integrated circuits (ASICs), central processing units (CPUs), graphics processing units (GPUs), cryptoprocessors (specialized processors that execute cryptographic algorithms within hardware), server processors, or any other suitable processing devices. The electrical device 2600 may include a memory 2604, which may itself include one or more memory devices such as volatile memory (e.g., dynamic random access memory (DRAM)), nonvolatile memory (e.g., read-only memory (ROM)), flash memory, solid state memory, and/or a hard drive. In some examples, the memory 2604 may include memory that shares a die with the processor circuitry 2602. This memory may be used as cache memory and may include embedded dynamic random access memory (eDRAM) or spin transfer torque magnetic random access memory (STT-MRAM).

In some examples, the electrical device 2600 may include a communication chip 2612 (e.g., one or more communication chips). For example, the communication chip 2612 may be configured for managing wireless communications for the transfer of data to and from the electrical device 2600. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some examples they might not.

The communication chip 2612 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2505 Amendment), Long-Term Evolution (LTE) project along with any amendments, updates, and/or revisions (e.g., advanced LTE project, ultra mobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication chip 2612 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication chip 2612 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication chip 2612 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication chip 2612 may operate in accordance with other wireless protocols in other examples. The electrical device 2600 may include an antenna 2622 to facilitate wireless communications and/or to receive other wireless communications (such as AM or FM radio transmissions).

In some examples, the communication chip 2612 may manage wired communications, such as electrical, optical, or any other suitable communication protocols (e.g., the Ethernet). As noted above, the communication chip 2612 may include multiple communication chips. For instance, a first communication chip 2612 may be dedicated to shorter-range wireless communications such as Wi-Fi or Bluetooth, and a second communication chip 2612 may be dedicated to longer-range wireless communications such as global positioning system (GPS), EDGE, GPRS, CDMA, WiMAX, LTE, EV-DO, or others. In some examples, a first communication chip 2612 may be dedicated to wireless communications, and a second communication chip 2612 may be dedicated to wired communications.

The electrical device 2600 may include battery/power circuitry 2614. The battery/power circuitry 2614 may include one or more energy storage devices (e.g., batteries or capacitors) and/or circuitry for coupling components of the electrical device 2600 to an energy source separate from the electrical device 2600 (e.g., AC line power).

The electrical device 2600 may include a display 2606 (or corresponding interface circuitry, as discussed above). The display 2606 may include any visual indicators, such as a heads-up display, a computer monitor, a projector, a touchscreen display, a liquid crystal display (LCD), a light-emitting diode display, or a flat panel display.

The electrical device 2600 may include an audio output device 2608 (or corresponding interface circuitry, as discussed above). The audio output device 2608 may include any device that generates an audible indicator, such as speakers, headsets, or earbuds.

The electrical device 2600 may include an audio input device 2624 (or corresponding interface circuitry, as discussed above). The audio input device 2624 may include any device that generates a signal representative of a sound, such as microphones, microphone arrays, or digital instruments (e.g., instruments having a musical instrument digital interface (MIDI) output).

The electrical device 2600 may include GPS circuitry 2618. The GPS circuitry 2618 may be in communication with a satellite-based system and may receive a location of the electrical device 2600, as known in the art.

The electrical device 2600 may include any other output device 2610 (or corresponding interface circuitry, as discussed above). Examples of the other output device 2610 may include an audio codec, a video codec, a printer, a wired or wireless transmitter for providing information to other devices, or an additional storage device.

The electrical device 2600 may include any other input device 2620 (or corresponding interface circuitry, as discussed above). Examples of the other input device 2620 may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

The electrical device 2600 may have any desired form factor, such as a hand-held or mobile electrical device (e.g., a cell phone, a smart phone, a mobile internet device, a music player, a tablet computer, a laptop computer, a netbook computer, an ultrabook computer, a personal digital assistant (PDA), an ultra mobile personal computer, etc.), a desktop electrical device, a server or other networked computing component, a printer, a scanner, a monitor, a set-top box, an entertainment control unit, a vehicle control unit, a digital camera, a digital video recorder, or a wearable electrical device. In some examples, the electrical device 2600 may be any other electronic device that processes data.

“Including” and “comprising” (and all forms and tenses thereof) are used herein to be open ended terms. Thus, whenever a claim employs any form of “include” or “comprise” (e.g., comprises, includes, comprising, including, having, etc.) as a preamble or within a claim recitation of any kind, it is to be understood that additional elements, terms, etc., may be present without falling outside the scope of the corresponding claim or recitation. As used herein, when the phrase “at least” is used as the transition term in, for example, a preamble of a claim, it is open-ended in the same manner as the term “comprising” and “including” are open ended. The term “and/or” when used, for example, in a form such as A, B, and/or C refers to any combination or subset of A, B, C such as (1) A alone, (2) B alone, (3) C alone, (4) A with B, (5) A with C, (6) B with C, or (7) A with B and with C. As used herein in the context of describing structures, components, items, objects and/or things, the phrase “at least one of A and B” is intended to refer to implementations including any of (1) at least one A, (2) at least one B, or (3) at least one A and at least one B. Similarly, as used herein in the context of describing structures, components, items, objects and/or things, the phrase “at least one of A or B” is intended to refer to implementations including any of (1) at least one A, (2) at least one B, or (3) at least one A and at least one B. As used herein in the context of describing the performance or execution of processes, instructions, actions, activities and/or steps, the phrase “at least one of A and B” is intended to refer to implementations including any of (1) at least one A, (2) at least one B, or (3) at least one A and at least one B. Similarly, as used herein in the context of describing the performance or execution of processes, instructions, actions, activities and/or steps, the phrase “at least one of A or B” is intended to refer to implementations including any of (1) at least one A, (2) at least one B, or (3) at least one A and at least one B.

As used herein, singular references (e.g., “a”, “an”, “first”, “second”, etc.) do not exclude a plurality. The term “a” or “an” object, as used herein, refers to one or more of that object. The terms “a” (or “an”), “one or more”, and “at least one” are used interchangeably herein. Furthermore, although individually listed, a plurality of means, elements or method actions may be implemented by, e.g., the same entity or object. Additionally, although individual features may be included in different examples or claims, these may possibly be combined, and the inclusion in different examples or claims does not imply that a combination of features is not feasible and/or advantageous.

Example 1 includes an apparatus comprising a first layer, and a thin film capacitor including a second layer on the first layer, the second layer defining a plurality of openings, and a third layer disposed on the first layer and in the plurality of openings, the second layer and the third layer corresponding to electrodes of a capacitor, and a fourth layer disposed between the first layer and the second layer, the third layer including an oxidized material, the third layer forming a dielectric of the capacitor.

Example 2 includes the apparatus of example 1, wherein the oxidized material is aluminum oxide.

Example 3 includes the apparatus of example 1, wherein the second layer is composed of aluminum.

Example 4 includes the apparatus of example 1, wherein the plurality of openings includes a first trench and a second trench, the first trench has a first width, the second trench has a second width, the first width substantially equal to the second width.

Example 5 includes the apparatus of example 1, wherein the plurality of openings is arranged in a grid.

Example 6 includes the apparatus of example 1, wherein the plurality of openings include a plurality of irregular pores.

Example 7 includes the apparatus of example 1, wherein the apparatus is an integrated circuit package.

Example 8 includes a package substrate for an integrated circuit package, the package substrate comprising a first electrode including a first hole and a second hole, a second electrode adjacent the first electrode, the second electrode including a first portion disposed within the first hole and a second portion disposed within the second hole, and a dielectric material separating the first electrode and the second electrode, the dielectric material including an oxide of a first material of the first electrode.

Example 9 includes the package substrate of example 8, wherein the first material is aluminum.

Example 10 includes the package substrate of example 8, wherein the second electrode includes copper.

Example 11 includes the package substrate of example 8, wherein the first electrode includes a first layer of the first material and a second layer of a second material different than the first material.

Example 12 includes the package substrate of example 8, wherein the first hole is a first square having a first width, the second hole is a second square having a second width, the first width substantially equal to the second width.

Example 13 includes the package substrate of example 8, wherein the first electrode includes a plurality of holes including the first hole and the second hole, the plurality of holes arranged in a grid.

Example 14 includes the package substrate of example 8, wherein the first hole and the second hole correspond to separate pores in an irregular pore network of the first material.

Example 15 includes a method to manufacture a capacitor in a package substrate the method including depositing a first layer of a first material, applying an anodic oxidation bath to provide a film of a second material on the first material and in an opening in the first layer, and depositing a third layer of a third material on the first layer.

Example 16 includes the method of example 15, wherein the first material is aluminum, the second material is aluminum oxide, and the film is formed by the application of the anodic oxidation bath.

Example 17 includes the method of example 15, wherein the opening is a first opening, the method further including providing a plurality of openings in the first layer, the plurality of openings arranged in a grid.

Example 18 includes the method of example 15, wherein the anodic oxidation bath has a pH of less than 5, the first opening provided via the application of the anodic oxidation bath.

Example 19 includes the method of example 15, further including depositing a filler in the opening.

Example 20 includes the method of example 15, further including depositing a fourth layer of a fourth material on the first layer, the film formed by the application of the anodic oxidation bath to the fourth layer.

From the foregoing, it will be appreciated that example systems, methods, apparatus, and articles of manufacture have been disclosed that improve the capacitance density of substrate packages. Examples disclosed herein have greater capacitance densities than similar capacitors of a same footprint due to the trenches formed in the bottom electrode and/or the porous network formed in the dielectric layer.

What is claimed is:

1. An apparatus comprising:
a first layer; and
a thin film capacitor including:
a second layer on the first layer, the second layer defining a plurality of openings; and
a third layer disposed on the first layer and in the plurality of openings, the second layer and the third layer corresponding to electrodes of a capacitor; and
a fourth layer disposed between the first layer and the second layer, the third layer including an oxidized material, the third layer forming a dielectric of the capacitor.

2. The apparatus of claim 1, wherein the oxidized material is aluminum oxide.

3. The apparatus of claim 1, wherein the second layer is composed of aluminum.

4. The apparatus of claim 1, wherein the plurality of openings includes a first trench and a second trench, the first trench has a first width, the second trench has a second width, the first width substantially equal to the second width.

5. The apparatus of claim 1, wherein the plurality of openings is arranged in a grid.

6. The apparatus of claim 1, wherein the plurality of openings include a plurality of irregular pores.

7. The apparatus of claim 1, wherein the apparatus is an integrated circuit package.

8. A package substrate for an integrated circuit package, the package substrate comprising:
a first electrode including a first hole and a second hole;
a second electrode adjacent the first electrode, the second electrode including a first portion disposed within the first hole and a second portion disposed within the second hole; and
a dielectric material separating the first electrode and the second electrode, the dielectric material including an oxide of a first material of the first electrode.

9. The package substrate of claim 8, wherein the first material is aluminum.

10. The package substrate of claim 8, wherein the second electrode includes copper.

11. The package substrate of claim 8, wherein the first electrode includes a first layer of the first material and a second layer of a second material different than the first material.

12. The package substrate of claim 8, wherein the first hole is a first square having a first width, the second hole is a second square having a second width, the first width substantially equal to the second width.

13. The package substrate of claim 8, wherein the first electrode includes a plurality of holes including the first hole and the second hole, the plurality of holes arranged in a grid.

14. The package substrate of claim 8, wherein the first hole and the second hole correspond to separate pores in an irregular pore network of the first material.

15. A method to manufacture a capacitor in a package substrate the method including:
depositing a first layer of a first material;
applying an electric field in an anodic oxidation bath to provide a film of a second material on the first material and in an opening in the first layer; and
depositing a third layer of a third material on the first layer.

16. The method of claim 15, wherein the first material is aluminum, the second material is aluminum oxide, and the film is formed by the application of an electric field in the anodic oxidation bath.

17. The method of claim 15, wherein the opening is a first opening, the method further including providing a plurality of openings in the first layer, the plurality of openings arranged in a grid.

18. The method of claim 15, wherein the anodic oxidation bath has a pH of less than 5, the first opening provided via the application of an electric field in the anodic oxidation bath.

19. The method of claim 15, further including depositing a filler in the opening.

20. The method of claim 15, further including depositing a fourth layer of a fourth material on the first layer, the film formed by the application of an electric field in the anodic oxidation bath to the fourth layer.
